(19) United States
(12) Patent Application Publication
(10) Pub. No.: US 2020/0265334 A1
(43) Pub. Date: Aug. 20, 2020

(54) IMPROVED QUBIT DESIGNS FOR QUANTUM CIRCUITS

(71) Applicants: INTEL CORPORATION, Santa Clara, CA (US); TECHNISCHE UNIVERSITEIT DELFT, Delft (NL); NEDERLANDSE ORGANISATIE VOOR TOEGEPASTNATUURWETENSCHAPPELIJK ONDERZOEK TNO, s-Gravenhage (NL)

(72) Inventors: Syeda Nadia Haider, Berkel en Rodenrijs (NL); Stefano Poletto, Nootdorp (NL); Leonardo Dicarlo, Delft (NL); Alessandro Bruno, Delft (NL); David J. Michalak, Portland, OR (US)

(73) Assignees: INTEL CORPORATION, Santa Clara, CA (US); TECHNISCHE UNIVERSITEIT DELFT, Delft (NL); NEDERLANDSE ORGANISATIE VOOR TOEGEPASTNATUURWETENSCHAPPELIJK ONDERZOEK TNO, 's-Gravenhage (NL)

(21) Appl. No.: 16/651,529

(22) PCT Filed: Dec. 15, 2017
(86) PCT No.: PCT/US2017/066552

§ 371 Date: Mar. 27, 2020

(51) Int. Cl. G06N 10/00; H01L 27/18; H01L 29/66

(52) U.S. Cl. CPC G06N 10/00; H01L 29/66977; H01L 27/18

(57) ABSTRACT

Embodiments of the present disclosure provide improved layout designs for quantum circuit assemblies employing qubits, e.g. superconducting qubits. One proposed design involves increasing a capacitance between a first qubit and a coupling component that couples the first qubit to a second qubit. Another design involves rounding of one or more corners at the end portions of coupling components. Yet another design involves varying the distance between two electrically conductive elements of a given superconducting qubit device which are connected to one another via one or more non-linear inductive elements. Qubit layout designs described herein may help increase coupling strength between qubits, allow greater design flexibility in achieving faster multi-qubit gates, and/or reduce or mitigate the negative effects of two-level systems.

### TECHNICAL FIELD

This disclosure relates generally to the field of quantum computing, and more specifically, to various layout designs for quantum circuits and to methods of fabrication thereof.

### BACKGROUND

Quantum computing refers to the field of research related to computation systems that use quantum-mechanical phenomena to manipulate data. These quantum-mechanical phenomena, such as superposition (in which a quantum variable can simultaneously exist in multiple different states) and entanglement (in which multiple quantum variables have related states irrespective of the distance between them in space or time), do not have analogs in the world of classical computing.

Quantum computers use so-called quantum bits, referred to as qubits (both terms “bits” and “qubits” often interchangeably refer to the values that they hold as well as to the actual devices that store the values). Similar to a bit of a classical computer, at any given time, a qubit can be either 0 or 1. However, in contrast to a bit of a classical computer, a qubit can also be 0 and 1 at the same time, which is a result of superposition of quantum states—a uniquely quantum-mechanical phenomenon. Entanglement also contributes to the unique nature of qubits in that input data to a quantum processor can be spread out among entangled qubits, allowing manipulation of that data to be spread out as well: providing input data to one qubit results in that data being shared to other qubits with which the first qubit is entangled.

Compared to well-established and thoroughly researched classical computers, quantum computing is still in its infancy, with the highest number of qubits in a solid-state quantum processor currently being below 100. One of the main challenges resides in protecting qubits from decoherence so that they can stay in their information-holding states long enough to perform the necessary calculations and read out the results.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of an exemplary superconducting quantum circuit, according to some embodiments of the present disclosure.

FIGS. 2-4 illustrate exemplary layout designs of quantum circuit assemblies with a superconducting qubit device capacitively coupled to 4-nearest neighbor quantum elements, according to various embodiments of the present disclosure.

FIG. 5 provides a flow chart of a method for fabricating quantum circuit assemblies with superconducting qubits arranged in accordance with layout designs described herein, according to some embodiments of the present disclosure.

FIGS. 6A and 6B are top views of a wafer and dies that may include one or more of quantum circuit assemblies with superconducting qubits arranged in accordance with any of the layout designs described herein, according to some embodiments of the present disclosure.

FIG. 7 is a schematic cross-sectional side view of a device assembly that may include one or more of quantum circuit assemblies with superconducting qubits arranged in accordance with any of the layout designs described herein, according to some embodiments of the present disclosure.

FIG. 8 is a block diagram of an exemplary quantum computing device that may include one or more of quantum circuit assemblies with superconducting qubits arranged in accordance with any of the layout designs described herein.

### DETAILED DESCRIPTION

### Overview

As briefly described above, quantum computing, or quantum information processing, refers to the field of research related to computation systems that use quantum-mechanical phenomena to manipulate data. One example of quantum-mechanical phenomena is the principle of quantum superposition, which asserts that any two or more quantum states can be added together, i.e. superposed, to produce another valid quantum state, and that any quantum state can be represented as a sum of two or more other distinct states. Quantum entanglement is another example of quantum-mechanical phenomena. Entanglement refers to groups of particles being generated or interacting in such a way that the state of one particle becomes intertwined with that of the others. Furthermore, the quantum state of each particle cannot be described independently. Instead, the quantum state is given for the group of entangled particles as a whole. Yet another example of quantum-mechanical phenomena is sometimes described as a “collapse” because it asserts that when we observe (measure) particles, we unavoidably change their properties in that, once observed, the particles cease to be in a state of superposition or entanglement (i.e. by trying to ascertain anything about the particles, we collapse their state).

Put simply, superposition postulates that a given particle can be simultaneously in two states, entanglement postulates that two particles can be related in that they are able to instantly coordinate their states irrespective of the distance between them in space and time, and collapse postulates that when one observes a particle, one unavoidably changes the state of the particle and its' entanglement with other particles. These unique phenomena make manipulation of data in quantum computers significantly different from that of classical computers (i.e. computers that use phenomena of classical physics). Therefore, both the industry and the academics continue to focus on a search for new and improved physical systems whose functionality could approach that expected of theoretically designed qubits.

Physical systems for implementing qubits that have been explored until now include e.g. superconducting qubits, silicon (Si) quantum dot qubits, single trapped ion qubits, photon polarization qubits, etc. Out of the various physical implementations of qubits, superconducting qubits are promising candidates for building a quantum computer, where, in general, superconducting qubits refer to qubit devices that operate based on Josephson effect which is a macroscopic quantum phenomenon of supercurrent, i.e. a current that, due to zero electrical resistance, flows indefinitely long without any voltage applied, across a non-linear inductive device known as a Josephson Junction. One challenge with qubits in general, and superconducting qubits in particular, remains in protecting qubits from decoherence (i.e. loss of state, and, therefore loss of information that a qubit is supposed to hold). For this reason, materials, fabrication methods, and layout designs used for building quantum circuits continuously focus on reducing spurious (i.e. unintentional and undesirable) two-level systems (TLS's), thought to be the dominant source of qubit decoherence, where, in general, as used in quantum mechanics, a two-level (also referred to as “two-state”) system is a system that can exist in any quantum superposition of two independent and physically distinguishable quantum states.

Embodiments of the present disclosure provide improved qubit designs for quantum circuit assemblies employing qubits which use one or more non-linear inductive elements such as e.g. Josephson Junctions and coupling components to couple to other qubits, e.g. superconducting qubits. Various qubit designs described herein may help increase coupling strengths, thus decrease the interaction time between qubits, allow greater design flexibility in achieving increased coupling strengths, and/or reduce or mitigate the negative effects of spurious TLS's. One proposed design involves increasing a capacitance between a first qubit and a coupling component (e.g. a coupling component on a neighboring qubit, a lumped element capacitor, a lumped element resonator, or a transmission line segment) and between a second qubit and the coupling component such that entanglement between the two qubits can occur quickly. Another design involves rounding of one or more corners at the end portions of the coupling components used to couple various qubits and rounding at the corresponding end portions of the qubit device close to the coupling elements. Yet another design involves varying the distance between two electrically conductive elements of a given qubit (such conductive elements are referred to in the following as “islands”), which are connected to one another via one or more non-linear inductive elements (e.g. Josephson Junctions). Any combination of two or more of these designs is also possible and is within the scope of the present disclosure.

In order to provide substantially lossless connectivity to, from, and between the qubits, some or all of the electrically conductive portions of various quantum circuit elements described herein (e.g. islands of the qubits, coupling components, readout resonators, microwave feed lines, drive lines, various ground planes, electrodes of Josephson Junctions and leads to such electrodes) may be made from one or more superconductive materials. However, some or all of these electrically conductive portions could be made from electrically conductive materials which are not superconductive. In the following, unless specified otherwise, reference to an electrically conductive material or circuit element implies that a superconductive material can be used, and vice versa (i.e. reference to a superconductor implies that a conductive material which is not superconductive may be used). Furthermore, any material described herein as a “superconductive/superconducting material” may refer to one or more materials, including alloys of materials, which exhibit superconducting behavior at typical qubit operating conditions (e.g. materials which exhibit superconducting behavior at very low temperatures at which qubits typically operate), but which may or may not exhibit such behavior at higher temperatures (e.g. at room temperatures). Examples of such materials include aluminum (Al), niobium (Nb), niobium nitride (NbN), titanium nitride (TiN), niobium titanium nitride (NbTiN), indium (In), and molybdenum rhenium (MoRe), all of which are particular types of superconductors at qubit operating temperatures, as well as their alloys.

While some descriptions are provided with reference to superconducting qubits, in particular to transmons, a particular class of superconducting qubits, at least some teachings of the present disclosure may be applicable to implementations of any qubits, including superconducting qubits other than transmons and/or including qubits other than superconducting qubits, which may employ non-linear inductive elements, such as Josephson Junctions and coupling components, all of which implementations are within the scope of the present disclosure. For example, the quantum circuit device assemblies described herein may be used in quantum circuits employing Si quantum dot qubits or nanowire transmons. In another example, the quantum circuit device assemblies described herein may be used in hybrid semiconducting-superconducting quantum circuits.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

In the drawings, some schematic illustrations of exemplary structures of various devices and assemblies described herein may be shown with precise right angles and straight lines, but it is to be understood that such schematic illustrations may not reflect real-life process limitations which may cause the features to not look so “ideal” when any of the structures described herein are examined using e.g. scanning electron microscopy (SEM) images or transmission electron microscope (TEM) images. In such images of real structures, possible processing defects could also be visible, such as e.g. not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Furthermore, the accompanying drawings are not necessarily drawn to scale.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

While the disclosure may use the singular term “layer,” the term “layer” should be understood to refer to assemblies that may include multiple different material layers.

In the following detailed description, various aspects of the illustrative implementations will be described using terms commonly employed by those skilled in the art to convey the substance of their work to others skilled in the art. For example, the terms “oxide,” “carbide,” “nitride,” etc. refer to compounds containing, respectively, oxygen, carbon, nitrogen, etc. The terms “substantially,” “close,” “approximately,” “near,” and “about,” generally refer to being within +/−20% of a target value based on the context of a particular value as described herein or as known in the art. Similarly, terms indicating orientation of various elements, such as e.g. “coplanar,” “perpendicular,” “orthogonal,” “parallel,” or any other angle between the elements, generally refer to being within +/−5-10% of a target value based on the context of a particular value as described herein or as known in the art. Furthermore, as used herein, terms indicating what may be considered an idealized behavior, such as e.g. “superconducting” or “lossless”, are intended to cover functionality that may not be exactly ideal but is within acceptable margins for a given application. For example, a certain level of loss, either in terms of non-zero electrical resistance or non-zero amount of spurious TLS's may be acceptable such that the resulting materials and structures may still be referred to by these “idealized” terms. Specific values associated with an acceptable level of loss are expected to change over time as fabrication precision will improve and as fault-tolerant schemes may become more tolerant of higher losses, all of which are within the scope of the present disclosure.

Still further, while the present disclosure may include references to microwave signals, this is done only because current qubits are designed to work with such signals because the energy in the microwave range is higher than thermal excitations at the temperature at which the qubits are typically operated. In addition, techniques for the control and measurement of microwaves are well known. For these reasons, typical frequencies of qubits are in 1-10 GHz, e.g. in 3-8 GHz, range, in order to be higher than thermal excitations, but low enough for ease of microwave engineering. However, advantageously, because excitation energy of qubits is controlled by the circuit elements, qubits can be designed to have any frequency. Therefore, in general, qubits could be designed to operate with signals in other ranges of electromagnetic spectrum and embodiments of the present disclosure could be modified accordingly. All of these alternative implementations are within the scope of the present disclosure.

### Quantum Computing and Josephson Junctions

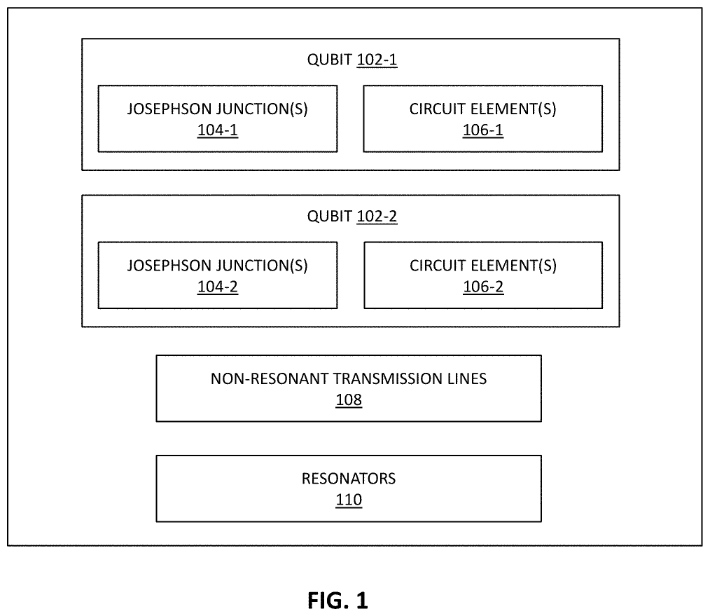

FIG. 1 provides a schematic illustration of an exemplary quantum circuit 100, e.g. a superconducting quantum circuit that may include any of the quantum circuit assemblies described herein.

As shown in FIG. 1, an exemplary quantum circuit 100 may include two or more qubits 102, e.g. superconducting qubits, (reference numerals following after a dash, such as e.g. qubit 102-1 and 102-2 indicate different instances of the same or analogous element). Each of the qubits 102 may include one or more non-linear inductive elements (e.g., Josephson Junctions) 104. Josephson Junctions are integral building blocks in superconducting quantum circuits where they form the basis of quantum circuit elements that can approximate functionality of theoretically designed qubits. In general, a Josephson Junction includes two superconductors coupled by a so-called weak link that weakens the superconductivity between the two superconductors. In quantum circuits, a weak link of a Josephson Junction may e.g. be implemented by providing a thin layer of an insulating, non-superconductive metal, or a semiconducting material, typically referred to as a “barrier” or a “tunnel barrier,” sandwiched, in a stack-like arrangement, between two layers of superconductor, which two superconductors serve as a first and a second electrode of a Josephson Junction. The Josephson Junction provides a non-linear inductive element to the circuit and allows the qubit to become an anharmonic oscillator. The anharmonicity is determined by the ratio of the charging energy, which stems from the total capacitance between a first and second element of the qubit, and the Josephson energy of the non-linear inductive element (e.g., Josephson Junction). The anharmonicity is what allows the state of the qubit to be controlled to a high level of fidelity. In addition to controlling the anharmonicity, the charging and Josephson energies also control the qubit frequency.

Typically, when a qubit employs only one Josephson Junction, a frequency of the qubit cannot be changed substantially beyond what is defined by the design unless one of the qubit capacitive elements is tunable. Employing two or more Josephson Junctions, e.g. arranged in a so-called superconducting quantum interference device (SQUID), allows controlling the frequency of the qubit, which, in turn, allows greater control as to whether and when the qubit interacts with other components of a quantum circuit, e.g. with other qubits. In general, a SQUID of a superconducting qubit includes a pair of Josephson Junctions and a loop of a conductive, typically superconductive material (i.e. a superconducting loop), connecting a pair of Josephson Junctions. Applying a net magnetic field in a certain orientation to the SQUID loop of a superconducting qubit allows controlling the frequency of the qubit. In particular, applying magnetic field to the SQUID region of a superconducting qubit is generally referred to as a “flux control” of a qubit, and the magnetic field is generated by providing direct-current (DC) or a pulse of current through an electrically conductive or superconductive line generally referred to as a “flux bias line” (also known as a “flux line” or a “flux coil line”). By providing flux bias lines sufficiently close to SQUIDs, magnetic fields generated as a result of currents running through the flux bias lines extend to the SQUIDs, thus tuning qubit frequencies.

Turning back to FIG. 1, within each qubit 102, the one or more Josephson Junctions 104 may be directly electrically connected to one or more other circuit elements 106, which, in combination with the Josephson Junction(s) 104, form a non-linear oscillator circuit providing multi-level quantum system where the first two to three levels define the qubit under normal operation. The circuit elements 106 could be e.g. shunt capacitors, superconducting loops of a SQUID, electrodes for setting an overall capacitance of a qubit, or/and ports for capacitively coupling the qubit to one or more of a readout resonator, a coupling or “bus” component, and a direct microwave drive line, or electromagnetically coupling the qubit to a flux bias line.

As also shown in FIG. 1, an exemplary quantum circuit 100 typically includes a plurality of non-resonant transmission lines 108, and a plurality of resonators 110. The non-resonant transmission lines 108 are typically used for providing microwave signals to different quantum circuit elements and components, which elements and components include e.g. readout resonators for various qubits, and may be considered to implement external readout and/or control of qubits. For example, for superconducting qubits, examples of the non-resonant transmission lines 108 include flux bias lines, microwave lines, and microwave drive lines. On the other hand, the resonators 110 may be viewed as implementing internal control lines for qubits. For superconducting qubits, examples of the resonators 100 include coupling and readout resonators.

In general, a resonator 110 of a quantum circuit differs from a non-resonant microwave transmission line 108 in that a resonator is deliberately designed to support resonant oscillations (i.e. resonance), under certain conditions. In contrast, non-resonant transmission lines may be similar to conventional microwave transmission lines in that they are designed to avoid resonances, especially resonances at frequencies/wavelengths close to the resonant frequencies/wavelengths of any resonant object used in the quantum computing circuits, e.g., qubits, bus resonators, or readout resonators in the proximity of such non-resonant lines. Once non-resonant transmission lines are manufactured, some of them may inadvertently support some resonances, but, during its design, efforts are taken to minimize resonances, standing waves, and reflected signals as much as possible, so that all of the signals can be transmitted through these lines without, or with as little resonance as possible.

On-chip capacitive coupling between quantum or control elements can be achieved either through use of coupling components such as a coupling component on a neighboring qubit, a lumped element capacitor, a lumped element resonator, or a transmission line segment. A resonator is a transmission line segment that is made by employing fixed boundary conditions, and these boundary conditions control the frequencies/wavelengths which will resonate within a given transmission line segment used to implement a resonator. In order to satisfy boundary conditions for resonance, each end of a transmission line segment resonator can be either a node, if it is shorted to ground (e.g. where one end of the transmission line segment structure is electrically connected to a ground plane), or an antinode, if it is capacitively or inductively coupled to ground or to another quantum circuit element. Thus, resonators 110 differ from non-resonant microwave transmission lines 108 in how these lines are terminated at the relevant ends. A line used to route a signal on a substrate, i.e. one of the non-resonant transmission lines 108, typically extends from a specific source, e.g. a bonding pad or another type of electrical connection to a source, to a specific load (e.g. a short circuit proximate to SQUID loop, a quantum dot device, another bonding pad, or another electrical connection to a load). In other words, non-resonant transmission lines 108 terminate with direct electrical connections to sources, ground sinks, and/or loads. On the other hand, a transmission line resonator is typically composed of a piece of transmission line terminated with either two open circuits (in case of a half-wavelength resonator) or an open and a short circuit (in case of a quarter-wavelength resonator). In this case, for a desired resonant frequency, transmission line length may e.g. be a multiple of a microwave wavelength divided by 2 or 4, respectively. However, other terminations are possible, for example capacitive or inductive, and in this case the required line length to support resonance will be different from that identified above. For example, capacitive terminations may be used for resonators which are coupled to qubits, to a feedline, line, or to another resonator by a capacitive interaction.

Besides line termination by capacitive or inductive coupling or a short circuit, in order to support resonant oscillations, transmission line segments of the resonators 110 need to be of a specific length that can support such oscillations. That is why, often times, resonators 110 may be laid out on a substrate longer than the actual distance would require (i.e. a non-resonant transmission line would typically be laid out to cover the distance in the most compact manner possible, e.g. without any curves, wiggles, or excess length, while a resonator may need to have curves, wiggles, and be longer than the shortest distance between the two elements the resonator is supposed to couple in order to be sufficiently long to support resonance).

One type of the resonators 110 used with superconducting qubits are so-called coupling resonators (also known as “bus resonators”), which provide one manner for coupling different qubits together in order to realize quantum logic gates. These types of resonators are analogous in concept and have analogous underlying physics as readout resonators, except that a coupling or “bus” resonator involves only capacitive couplings between two or more qubits whereas a readout resonator involves capacitive coupling between two or more qubits and a feedline. A coupling resonator may be implemented as a microwave transmission line segment that includes capacitive or inductive connections to ground on both sides (e.g. a half-wavelength resonator), which results in oscillations (resonance) within the transmission line. While the ends of a coupling resonator have open circuits to the ground, each side of a coupling resonator is coupled, either capacitively or inductively, to a respective (i.e. different) qubit by being in the appropriate location and sufficient proximity to the qubit. Because different regions of a coupling resonator have coupling with a respective different qubit, the two qubits are coupled together through the coupling resonator. Thus, coupling resonators may be employed for implementing logic gates.

Another type of the resonators 110 used with superconducting qubits are so-called readout resonators, which may be used to read the state(s) of qubits. In some embodiments, a corresponding readout resonator may be provided for each qubit. A readout resonator, similar to the bus coupling resonator, is a transmission line segment. On one end it may have an open circuit connection to ground as well as any capacitively or inductively coupled connections to other quantum elements or a non-resonant microwave feedline. On the other end, a readout resonator may either have a capacitive connection to ground (for a half-wavelength resonator) or may have a short circuit to the ground (for a quarter-wavelength resonator), which also results in oscillations within the transmission line, with the resonant frequency of the oscillations being close to the frequency of the qubit. A readout resonator is coupled to a qubit by being in the appropriate location and sufficient proximity to the qubit, again, either through capacitive or inductive coupling. Due to a coupling between a readout resonator and a qubit, changes in the state of the qubit result in changes of the resonant frequency of the readout resonator. In turn, changes in the resonant frequency of the readout resonator can be read externally via connections which lead to external electronics e.g. wire or solder bonding pads.

For the non-resonant transmission lines 108, some descriptions of flux bias lines were provided above and, in the interests of brevity are not repeated here. In general, running a current through a flux bias line, provided e.g. from a wirebonding pads or any other connection element, allows tuning (i.e. changing) the frequency of a corresponding qubit 102 to which a given flux bias line is connected. As a result of running the current in a given flux bias line, magnetic field is created around the line. If such a magnetic field is in sufficient proximity to a given qubit 102, e.g. by a portion of the flux bias line being provided next (sufficiently close) to the qubit 102, the magnetic field couples to the qubit, thereby changing the spacing between the energy levels of the qubit. This, in turn, changes the frequency of the qubit since the frequency is directly related to the spacing between the energy levels via the equation E=hν (Planck's equation), where E is the energy (in this case the energy difference between energy levels of a qubit), h is the Planck's constant and ν is the frequency (in this case the frequency of the qubit). As this equation illustrates, if E changes, then v changes. Different currents and pulses of currents can be sent down each of the flux lines allowing for independent tuning of the various qubits.

Typically, the qubit frequency may be controlled in order to bring the frequency either closer to or further away from another resonant item, for example a coupling resonator or a coupled neighbor qubit, to implement multi-qubit interactions, as may be desired in a particular setting.

For example, if it is desirable that a first qubit 102-1 and a second qubit 102-2 interact, via a coupling resonator (i.e. an example of the resonators 110) connecting these qubits, then both qubits 102 may need to be tuned to be at nearly the same frequency or a detuning equal, or nearly equal, to the anharmonicity. One way in which such two qubits could interact is that, if the frequency of the first qubit 102-1 is tuned very close to the resonant frequency of the coupling resonator, the first qubit can, when in the excited state, relax back down to the ground state by emitting a photon (similar to how an excited atom would relax) that would resonate within the coupling resonator. If the second qubit 102-2 is also at this energy (i.e. if the frequency of the second qubit is also tuned very close to the resonant frequency of the coupling resonator), then it can absorb the photon emitted from the first qubit, via the coupling resonator coupling these two qubits, and be excited from its ground state to an excited state. Thus, the two qubits interact, or are entangled, in that a state of one qubit is controlled by the state of another qubit. In other scenarios, two qubits could interact via exchange of virtual photons, where the qubits do not have to be tuned to be at the same frequency with one another. In general, two or more qubits could be configured to interact with one another by tuning their frequencies to specific values or ranges.

On the other hand, it may sometimes be desirable that two qubits coupled by a coupling resonator do not interact, i.e. the qubits are independent. In this case, by applying magnetic flux, by means of controlling the current in the appropriate flux bias line, to one qubit it is possible to cause the frequency of the qubit to change enough so that the photon it could emit no longer has the right frequency to resonate on the coupling resonator or on the neighboring qubit via a virtual photon transfer through the bus. If there is nowhere for such a frequency-detuned photon to go, the qubit will be better isolated from its surroundings and will live longer in its current state. Thus, in general, two or more qubits could be configured to reduce interactions with one another by tuning their frequencies to specific values or ranges.

The state(s) of each qubit 102 may be read by way of its corresponding readout resonator of the resonators 110. As explained below, the state of qubit 102 induces a shift in the resonant frequency in the associated readout resonator. This shift in resonant frequency can then be read out using its coupling to a feedline. To that end, an individual readout resonator may be provided for each qubit. As described above, a readout resonator may be a transmission line segment that includes a capacitive connection to ground on one side and is either shorted to the ground on the other side (for a quarter-wavelength resonator) or has a capacitive connection to ground (for a half-wavelength resonator), which results in oscillations within the transmission line (resonance) that depends upon the state of a proximal qubit. A readout resonator may be coupled to its corresponding qubit 102 by being in an appropriate location and sufficient proximity to the qubit, more specifically in an appropriate location and sufficient proximity to a first element (or “island”) of the qubit 102 that capacitively couples to the readout resonator, when the qubit is implemented as a transmon. Due to a coupling between the readout resonator and the qubit, changes in the state of the qubit result in changes of the resonant frequency of the readout resonator. In turn, by ensuring that the readout resonator is in sufficient proximity to a corresponding microwave feedline, changes in the resonant frequency of the readout resonator induce changes in the transmission coefficients of the microwave feedline which may be detected externally.

A coupling resonator, or, more generally, a coupling component, allows coupling different qubits together, e.g. as described above, in order to realize quantum logic gates. A coupling component could be comprised of a coupling component on a neighboring qubit, a lumped element capacitor, a lumped element resonator, or a transmission line segment. A coupling transmission line segment (e.g., coupling resonator or bus resonator) is similar to a readout resonator in that it is a transmission line segment that includes capacitive connections to various objects (e.g., qubits, ground, etc.) on both sides (i.e. a half-wavelength resonator), which also results in oscillations within the coupling resonator. Each side/end of a coupling component is coupled (again, either capacitively or inductively) to a respective qubit by being in appropriate location and sufficient proximity to the qubit, namely in sufficient proximity to a first element (or “island”) of the qubit that capacitively couples to the coupling component, when the qubit is implemented as a transmon. Because each side of a given coupling component has coupling with a respective different qubit, the two qubits are coupled together through the coupling component. Thus, coupling components may be employed in order to implement multi-qubit interactions.

In some implementations, a microwave line may be used to not only readout the state of the qubits as described above, but also to control the state of the qubits. When a single microwave line is used for this purpose, the line operates in a half-duplex mode where, at some times, it is configured to readout the state of the qubits, and, at other times, it is configured to control the state of the qubits. In other implementations, microwave lines may be used to only readout the state of the qubits as described above, while separate drive lines, may be used to control the state of the qubits. In such implementations, microwave lines used for readout may be referred to as readout lines, while microwave lines used for controlling the state of the qubits may be referred to as drive lines. Drive lines may control the state of their respective qubits 102 by providing to the qubits a microwave pulse at the qubit frequency, which in turn stimulates (i.e. triggers) a transition between the states of the qubit. By varying the length of this pulse, a partial transition can be stimulated, giving a superposition of the states of the qubit.

Flux bias lines, microwave lines, readout lines, drive lines, coupling components, and readout resonators, such as e.g. those described above, together form interconnects for supporting propagation of microwave signals. Further, any other connections for providing direct electrical interconnection between different quantum circuit elements and components, such as e.g. connections from electrodes of Josephson Junctions to plates of the capacitors or to superconducting loops of SQUIDs or connections between two ground lines of a particular transmission line for equalizing electrostatic potential on the two ground lines, may also be referred to as interconnects. Still further, the term “interconnect” may also be used to refer to elements providing electrical interconnections between quantum circuit elements and components and non-quantum circuit elements, which may also be provided in a quantum circuit, as well as to electrical interconnections between various non-quantum circuit elements provided in a quantum circuit. Examples of non-quantum circuit elements which may be provided in a quantum circuit may include various analog and/or digital systems, e.g. analog-to-digital converters, mixers, multiplexers, amplifiers, etc.

In various embodiments, various conductive circuit elements of supporting circuitry included in a quantum circuit such as the quantum circuit 100 could have different shapes and layouts. In general, the term “line” as used herein in context of signal lines or transmission lines does not imply straight lines, unless specifically stated so. For example, some resonant or non-resonant transmission lines or parts thereof (e.g. conductor strips of resonant or non-resonant transmission lines) may comprise more curves, wiggles, and turns while other resonant or non-resonant transmission lines or parts thereof may comprise less curves, wiggles, and turns, and some transmission lines or parts thereof may comprise substantially straight lines. At least some of the qubits 102 shown in FIG. 1, as well as the non-resonant transmission lines 108 and the resonators 110, may be implemented according to any of the improved layout designs described herein.

The qubits 102, the non-resonant transmission lines 108, and the resonators 110 of the quantum circuit 100 may be provided on, over, or at least partially embedded in a substrate (not shown in FIG. 1). The substrate may be any substrate suitable for realizing quantum circuit assemblies described herein. In one implementation, the substrate may be a crystalline substrate such as, but not limited to a silicon or a sapphire substrate, and may be provided as a wafer or a portion thereof. In other implementations, the substrate may be non-crystalline. In general, any material that provides sufficient advantages (e.g. sufficiently good electrical isolation and/or ability to apply known fabrication and processing techniques) to outweigh the possible disadvantages (e.g. negative effects of spurious TLS's), and that may serve as a foundation upon which a quantum circuit may be built, falls within the spirit and scope of the present disclosure. Additional examples of substrates include silicon-on-insulator (SOI) substrates, III-V substrates, and quartz substrates.

In various embodiments, quantum circuits such as the one shown in FIG. 1 may be used to implement components associated with a quantum integrated circuit (IC). Such components may include those that are mounted on or embedded in a quantum IC, or those connected to a quantum IC. The quantum IC may be either analog or digital and may be used in a number of applications within or associated with quantum systems, such as e.g. quantum processors, quantum amplifiers, quantum sensors, etc., depending on the components associated with the IC. The IC may be employed as part of a chipset for executing one or more related functions in a quantum system.

### Improved Layout Designs

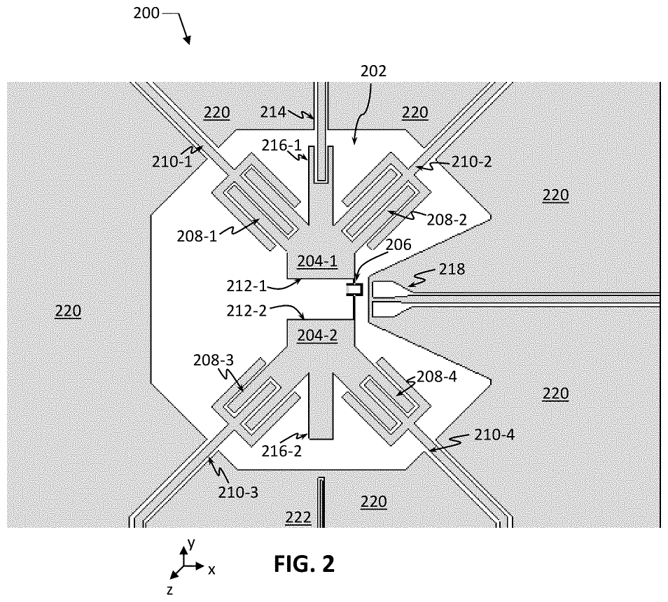

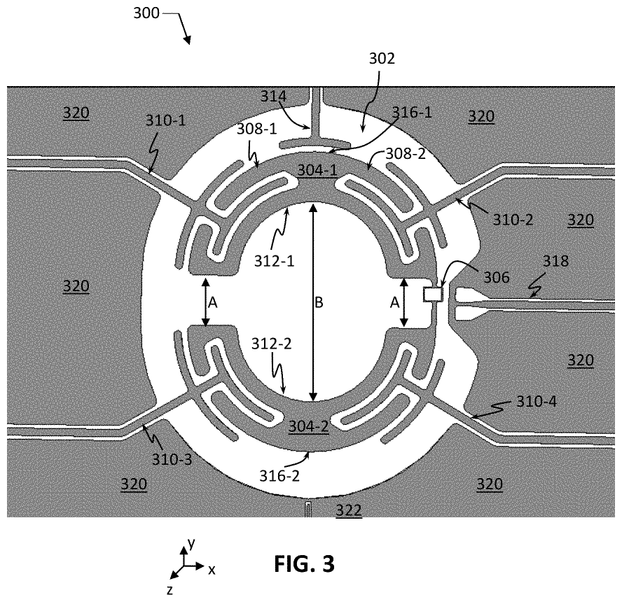

As was briefly summarized above, layout designs described herein may be seen as three different concepts: 1) increasing a capacitance between a first qubit and a coupling component in order to reduce gate/coupling time, 2) rounding of one or more corners at one or more end portions of a coupling component and the corresponding sections on the qubit, and 3) varying the distance between the islands of a superconducting qubit device. In various embodiments, these three concepts may, but do not have to, be combined with one another in any combination. These concepts will now be described with reference to FIGS. 2 and 3, illustrating exemplary layout designs of quantum circuit assemblies where individual superconducting qubits have four nearest neighbors, according to various embodiments of the present disclosure. It is, however, to be understood that the descriptions provided herein are equally applicable to quantum circuit assemblies with qubits having any other number (any one or more) of nearest neighbors, and that the term “nearest neighbors” refers to neighbors which may be at different distances from a given qubit, as long as they are more highly capacitively coupled to the given qubit than other qubits.

In both FIGS. 2 and 3, the grey portions illustrate elements patterned from an electrically superconductive material (which may include any one or more materials such as e.g. superconductive materials listed above), while the white portions illustrate portions of an insulating material, e.g. portions of the substrate exposed by removal of the superconductive material.

At the bottom of each of FIGS. 2 and 3 an exemplary coordinate system x-y-z is illustrated so that various dimensions described herein may be referred to a particular axis x, y, or z along which the dimensions are measured. The views of each of FIGS. 2 and 3 are of the x-y plane of such a coordinate system.

FIG. 2 illustrates a quantum circuit assembly 200 showing a superconducting qubit device 202. The qubit device 202 may be viewed as including two islands made of a superconductive material, shown in FIG. 2 as a first island 204-1 and a second island 204-2. Each of the two islands 204 has a direct electrical connection to at least one non-linear inductive element such as e.g. a Josephson Junction, but in FIG. 2 each of the two islands is shown to have a direct electrical connection to a SQUID 206 (schematically shown in FIG. 2 as a loop, representing the superconducting loop of a SQUID). In this manner, the first and second islands 204-1 and 204-2 are connected to one another via one or more non-linear inductive elements such as e.g. Josephson Junctions, e.g. via the SQUID 206.

Various portions of the islands 204-1 and 204-2 are labeled in FIG. 2 with their own reference numerals in order to differentiate their functionality from other portions. For example, each of the islands 204-1 and 204-2 include portions 208 used to capacitively couple to an end portion of a respective coupling component, e.g., in this case a coupling resonator formed by a transmission line segment, 210. Thus, FIG. 2 illustrates a portion 208-1 of the first island 204-1 being capacitively coupled to a first coupling resonator 210-1, a portion 208-2 of the first island 204-1 being capacitively coupled to a second coupling resonator 210-2, a portion 208-3 of the second island 204-2 being capacitively coupled to a third coupling resonator 210-3, and a portion 208-4 of the second island 204-2 being capacitively coupled to a fourth coupling resonator 210-4. Each of the coupling resonators 210 may couple the qubit 202 to an individual other superconducting qubit (these further qubits not shown in the view of FIG. 2), and may implement a coupling resonator of the resonators 110 described above.

Also shown in FIG. 2 are portions 212 of each of the islands 204-1 and 204-2, which portions provide the greatest contribution to the capacitance between the islands 204-1 and 204-2 (since portions 212 are opposite one another and are the closest to one another, compared to other portions of the islands 204). Thus, FIG. 2 illustrates a portion 212-1 of the first island 204-1 being opposite to a portion 212-2 of the second island 204-2. In the embodiment shown in FIG. 2, the distance between two such portions 212-1 and 212-2 (i.e. a dimension measured along the y-axis in the coordinate system shown in FIGS. 2-3) is substantially the same across these opposite portions. For example, in various embodiments, the distance between portions 212-1 and 212-2 may be between about 20 and 200 micrometers (um), including all values and ranges therein, e.g. between about 20 and 100 um, or between about 30 and 60 um. However, in other embodiments, this distance may vary, as shown e.g. in FIG. 3.

FIG. 2 further illustrates a readout resonator 214, capacitively coupled to a portion 216-1 of the first island 204-1. The readout resonator 214 may be a readout resonator of the resonators 110 described above. For symmetry, as shown in FIG. 2, in some embodiments the second island 204-2 may also have a similar portion 216-2, which may be coupled to a microwave drive line 222, for controlling the state of the qubit.

FIG. 2 further illustrates a flux bias line 218 provided in the vicinity of the SQUID 206 in order to tune the frequency of the qubit 202, as described above with reference to FIG. 1. The flux bias line 218 may be a flux bias line of the non-resonant transmission lines 108 described above. Finally, FIG. 2 also illustrates ground planes 220, i.e. portions of electrically conductive, preferably superconductive, material connected to the ground or some other reference potential, surrounding the qubit 202.

The first concept of a qubit design described herein, i.e. increasing a capacitance between a first qubit and a coupling component (which may also be called the “bus” or “coupling” component, and may e.g. be a coupling resonator) in order to decrease the gate or coupling time, is based on an insight that a given qubit design has a certain total capacitance that is electrically parallel to the Josephson Junction thereby forming a non-linear LC circuit, the total capacitance of the qubit being a combination of the individual capacitances, and that qubit frequency is a function of this total capacitance, the Josephson energy, and the qubit anharmonicity. In order to operate a superconducting qubit in the transmon regime, the charging energy of the total capacitance should be substantially larger than (e.g., 10 to 40 times larger than) the Josephson energy of the one or more Josephson Junctions employed in the qubit. Thus, in order to operate a transmon qubit, e.g. the qubit 202, at a certain frequency, or a range of frequencies, e.g. between 3 and 8 GHz, a total capacitance should be within a certain range, which may be referred to as a “budget” for the total capacitance. This budget includes e.g. capacitance between the first and second islands 204-1 and 204-2, the largest portion of which is due to the portions 212-1 and 212-2 being opposite of one another, capacitance between various portions of the islands 204 and the ground plane 220, capacitances between coupling resonators 210 and respective portions 208 of the qubit 202, capacitances between the coupling resonators 210 and the ground plane 220, and capacitances between all of these objects and any other metallic objects above or below the qubit plane. Out of these various capacitances contributing to the total capacitance budget, conventionally, capacitance between the first and second islands of a qubit has been the dominant one. In contrast, the first concept of the qubit design described herein is based on recognition that this capacitance may be decreased so that capacitances between portions of a qubit and one or more coupling components may be increased while keeping the charging energy, anharmonicity, and total capacitance, and therefore also the qubit frequency, substantially similar. Increasing a capacitance between a portion of the qubit and a coupling component coupling the qubit to another qubit shortens the times it takes to entangle the two qubits. As a result, the chances that the two qubits have time to interact before one or both of them decohere may be increased, resulting in improved operation of a quantum device implementing such designs and layouts. Accordingly, in some embodiments of the present disclosure, a capacitance between a coupling component and a portion of a qubit that is capacitively coupled to the coupling component (which may be referred to as “C_{bus}”) may be greater than a capacitance between the two islands of the qubit (which may be referred to as “C_{islands}”), e.g. a capacitance between the coupling resonator 210-1 and the portion 208-1 of the first island 204-1 (or, similarly, a capacitance between any other one of the coupling resonators 210 and a corresponding portion 208 of the first or the second islands) may be greater than a capacitance between the first island 204-1 and the second island 204-2. For example, in some embodiments, C_{bus} may be greater than about 2·C_{islands}, e.g. greater than about 3·C_{islands}, or greater than about 10·C_{islands}.

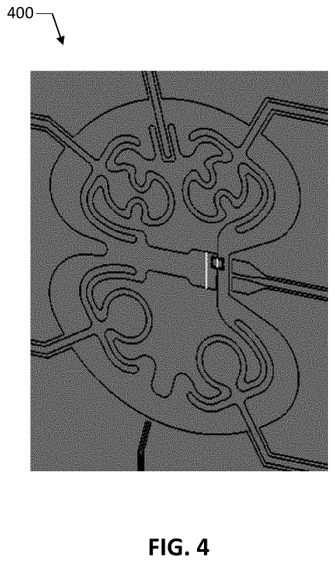

One way to increase the capacitance C_{bus} may be to increase the area where a portion of the coupling resonator faces a corresponding portion of the qubit, which may be done e.g. by modifying the geometries of these portions to introduce turns and wiggles, such as for example a case for a capacitor with an interlocking puzzle-piece shape or an interdigitated capacitor. The interdigitated geometry is schematically illustrated in the layout design shown in FIG. 2 where portions 208 of the qubit 202 are shown to form interdigitated capacitors with the ends of the corresponding coupling resonators 210 which are closest to such portions. While FIG. 2 illustrates each such interdigitated capacitor as having two fingers on the side of the respective portion 208 and having three fingers on the end side of the corresponding coupling resonator 210, in other embodiments, any other number of fingers of interdigitated capacitors may be used. Furthermore, descriptions provided with respect to FIG. 2 are equally applicable to embodiments where a shape of a portion of any coupling resonator 210 coupled to respective portion 208 of the qubit 202 is meandering (i.e. following a winding course, or comprising a plurality of convex and concave portions) and conformal to a shape of the portion 208, such two portions (i.e. a portion of any coupling resonator 210 and a respective portion 208) separated by a thin gap as to form a capacitor of an interlocking puzzle-piece shape, e.g. an interdigitated capacitor with one or more rounded corners. A general interlocking puzzle-piece shape of coupling components and portions of a qubit is illustrated in a quantum circuit assembly shown in FIG. 4, which includes elements analogous to those shown in FIGS. 2 and/or 3, which elements, therefore, are not described in detail. Still further, descriptions provided with respect to FIG. 2 are also applicable to embodiments where the area, and hence the capacitance C_{bus}, is increased by employing a parallel-plate geometry where portions 208 of the qubit 202 and ends of the corresponding coupling resonators 210 are in different planes parallel to one another, and are separated from one another by a thin gap as to form a parallel-plate capacitor. Any combination of one or more of these embodiments may be applied to increasing the capacitance C_{bus} in accordance with the principles described herein and, therefore, are within the scope of the present disclosure. Other ways of increasing capacitance as known in the art, e.g. increasing the dielectric constant of the substrate material, are within the scope of the present disclosure as well.

One way to decrease the capacitance C_{islands} may be to make portions 212-1 and 212-2 which are facing one another smaller, i.e. decreasing the area of the portions opposite one another. In some embodiments, a length of at least one of the portions 212-1 or 212-2 (i.e. a dimension measured along the x-axis of the coordinate system shown in FIGS. 2 and 3) may be between about 1 and 500 um, including all values and ranges therein, e.g. between about 50 and 150 um, or between about 80 and 120 um. Another way may be to place the portions 212-1 and 212-2 further away from one another. Other ways of decreasing capacitance as known in the art, e.g., decreasing the dielectric constant of the substrate material, and/or by removing substrate material through a control etch of the substrate (e.g. using a deep reactive ion etch (DRIE) technique), may be applied to decreasing the capacitance C_{islands} in accordance with the principles described herein and, therefore, are within the scope of the present disclosure.

When decreasing the gate or coupling time between a first qubit and a second qubit by increasing in the capacitance C_{bus}, n order to not substantially affect the qubit resonant frequency or anharmonicity, a concomitant decrease in the capacitance between one or more portions of the qubit 202 and the ground 220 (which may be referred to as “C_{ground}”) may be implemented to achieve a substantially similar total capacitance across the two islands of the qubit which are coupled to the non-linear inductive element. For example, in some embodiments, a capacitance C_{ground} may be made smaller than the capacitance C_{islands}, e.g. a capacitance between any one or more portions of the first island 204-1 or the second island 204-2 and an opposite portion of the ground plane 220 may be made smaller than a capacitance between the coupling resonator 210-1 and the portion 208-1 of the first island 204-1 (or, similarly, a capacitance between any other one of the coupling resonators 210 and a corresponding portion 208 of the first or the second islands). One way to decrease the capacitance C_{ground} may be to increase the distance between various conductive elements of the qubit 202 and the ground 220. Other ways of decreasing capacitance, e.g., decreasing the dielectric constant of the substrate material, locally removing the substrate material through e.g. a DRIE process, as known in the art may be applied to decreasing the capacitance C_{ground} in accordance with the principles described herein and, therefore, are within the scope of the present disclosure.

While the layout design of the quantum circuit assembly 200 already provides substantial advantages over conventional layout designs of qubits, further improvements could be made. One such improvement is based on a realization of the inventors of the present disclosure that having relatively sharp corners of the conductive elements of the qubit 202 and/or conductive elements in the vicinity of the qubit 202, e.g. of the coupling resonators 210, may not be the most optimal because sharp corners/angles of conductive elements can create high values of electrical field concentrated around them. Higher concentration of electrical field at metal/dielectric or metal/air interfaces can increase loss due to interface impurity, hence possibly reducing the resonator quality factor and qubit decoherence times. This realization is the basis of the second concept for improving a layout design of qubits described herein, which, although not specifically shown in FIG. 2, may be explained with reference to FIG. 2. Namely, according to this concept, one or more corners at the end portions of coupling components, e.g. the ends of the coupling resonators 210 may be curved, e.g. rounded. For example, in some embodiments, one or more of the corners of the coupling resonator 210-1 (as well as of other coupling resonators 210) shown in FIG. 2 as being of a substantially 90 degree angle, may be curved, e.g. rounded. In order to maintain substantially the same distance between each point of the end portion of the coupling resonator 210 and the corresponding portion 208 of the qubit 202, the corners of the corresponding portion 208 could also be curved, to follow the shape of the rounded corner portions of the coupling resonator 210. For example, corners of the end portion of the coupling resonator 210 which, when curved/rounded, result in a convex shape may be complemented with corners of corresponding portions of the portion 208 of the qubit 202 being made concave, with dimensions and curvature being complementary to those of the convex curved portions. In various embodiments, at least a portion of each curved portion of an end of a coupling resonator 210 may be implemented by having a plurality of straight portions at an angle to one another (i.e. such a curved portion would not have a circular/oval shape, but rather a shape of plurality of straight lines approximating a circular/oval shape). In some embodiments, the radius of curvature of the curved portions of the qubit 202 which are made of conductive materials, and of the curved portions of the ends of the coupling resonators 210, in particular curved fingers of the interdigitated capacitors provided at the end portions of the coupling resonator 210, may have a radius greater than about 1/100000^{th} of the free-space wavelength at the qubit operating frequency (e.g. for a qubit frequency of 6 GHz, the free-space wavelength is 50 millimeters (mm), and, therefore the radius may be greater than 50 mm/100000=0.5 micrometers (um)). In various embodiments, at least 80% of the curved portions provided in a quantum circuit assembly may have such a curvature.

Decreasing electric fields by rounding off sharp corners may be particularly advantageous for superconducting qubits in terms of spurious TLS's, as explained below.

One major source of loss and thus decoherence in superconducting qubits is thought to be attributable to spurious TLS's in the areas surrounding the qubits, e.g. TLS's in dielectric materials which may be not highly crystalline, such as e.g. the substrates on which quantum circuits are built. These TLS's are thought to be either an electron or an ion that can tunnel between two spatial states, which are caused either by defects in the crystal structure of the substrate or through polar impurities such as hydroxyl (OH—) groups. One mechanism of how spurious TLS's can lead to decoherence in a qubit is based on the idea that, if the TLS's are in a close proximity to the qubit and are in resonance with the qubit (i.e. when the frequency of a spurious TLS is close to the frequency of a qubit), they can couple to it. When this happens, spurious TLS's and the qubit exchange energy in the form of photons emitted by the qubit and absorbed by the spurious TLS's and may be viewed as a spurious TLS-qubit system having a certain combined energy. When combined energy of such a TLS-qubit system decays through phonon emission from the spurious TLS's, the TLS-qubit system relaxes, leading to decoherence of the qubit. Spurious TLS's that lead to qubit decoherence by this mechanism may be present at the surface of superconductive materials (i.e. TLS's present at the superconductor-air interface), at an interface between the substrate and the superconductive layer portions of the qubit, or/and at an interface between the substrate and the air. This problem is thought to be made even worse at areas of higher concentration of electromagnetic fields, which are typically areas around sharp corners/angles at metal/dielectric interfaces (i.e. at the interfaces of an electrically conductive materials of the supporting circuitry and the dielectric material of the substrate, or air.) Hence, rounding the corners may decrease the concentration of electromagnetic fields and, consequently, improve (increase) coherence times of superconducting qubits. A quantum circuit assembly 300 shown in FIG. 3 illustrates an example of such rounded corners.

FIG. 3 illustrates a quantum circuit assembly 300 showing a superconducting qubit device 302. The qubit device 302 is similar to the device 202 shown in FIG. 2 in the portions it includes and therefore, unless stated otherwise, descriptions and considerations provided with respect to the quantum circuit assembly shown in FIG. 2 are applicable to the quantum circuit assembly shown in FIG. 3. For example, the qubit device 302 may be viewed as including two islands made of a superconductive material, shown in FIG. 3 as a first island 304-1 and a second island 304-2. Each of the two islands 304 has a direct electrical connection to at least one Josephson Junction, but in FIG. 3 each of the two islands is shown to have a direct electrical connection to a SQUID 306 (schematically shown in FIG. 3 as a loop, representing the superconducting loop of a SQUID). In this manner, the first and second islands 304-1 and 304-2 are connected to one another via one or more Josephson Junctions, e.g. via the SQUID 306.

Similar to FIG. 2, various portions of the islands 304-1 and 304-2 are labeled in FIG. 3 with their own reference numerals in order to differentiate their functionality from other portions. For example, each of the islands 304-1 and 304-2 include portions 308 used to capacitively couple to an end portion of a respective coupling component, e.g., in this case a coupling resonator 310. Thus, FIG. 3 illustrates a portion 308-1 of the first island 304-1 being capacitively coupled to a first coupling resonator 310-1, a portion 308-2 of the first island 304-1 being capacitively coupled to a second coupling resonator 310-2, a portion 308-3 of the second island 304-2 being capacitively coupled to a third coupling resonator 310-3, and a portion 308-4 of the second island 304-2 being capacitively coupled to a fourth coupling resonator 310-4. Each of the coupling resonators 310 may couple the qubit 302 to an individual other superconducting qubit (these further qubits not shown in the view of FIG. 3), and may implement a coupling resonator of the resonators 110 described above.

Also shown in FIG. 3 are portions 312 of each of the islands 304-1 and 304-2 opposite one another. Thus, FIG. 3 illustrates a portion 312-1 of the first island 304-1 being opposite to a portion 312-2 of the second island 304-2. While in the layout design shown in FIG. 2, the distance between such portions was substantially the same, in the embodiment shown in FIG. 3, the distance between the portions 312-1 and 312-2 (i.e. a dimension measured along the y-axis in the coordinate system shown in FIGS. 2-3) varies. Namely, in the example shown in FIG. 3 the distance is smallest in areas of the qubit device where the distance is shown with an arrow A and is largest in the area where the distance is shown with an arrow B. In some embodiments, the distance between the first island 304-1 and the second island 304-2 (namely, the distance between the portions 312 of the first and second islands which are opposite one another) may vary by a factor of at least about 1.2, including all values and ranges therein, e.g. by a factor between about 1.5 and 10, or by a factor between about 1.5 and 5. Varying the distance between the opposing portions of the two islands of qubits may allow greater design flexibility in achieving reduced coupling times, and/or reduce or mitigate the negative effects of spurious TLS's. As described above, the example of FIG. 3 illustrates curved, e.g. rounded, corners of the coupling resonators 310 and corresponding curved corners of the opposite portions 208 of the first and second islands 304. However, in other embodiments, the variation in distance as shown in the example of FIG. 3 may be implemented without rounding of corners as also shown in this FIG. (i.e. the corners may be left relatively sharp, as e.g. illustrated in the drawing of FIG. 2). Similarly, the variations in distance between the portions 312 as shown in FIG. 3 may be applied to the example shown in FIG. 2, without rounding of the corners as shown in FIG. 3.

FIG. 3 further illustrates a readout resonator 314, capacitively coupled to a portion 316-1 of the first island 304-1. The readout resonator 314 may be a readout resonator of the resonators 110 described above, coupled to the first island 304-1, and a microwave drive line 322 shown in FIG. 3 may be coupled the second island 304-2, although, in alternative embodiments, the position of the readout resonator 314 and microwave drive line 322 may be swapped. FIG. 3 further illustrates a flux bias line 318 provided in the vicinity of the SQUID 306 in order to tune the frequency of the qubit 302, as described above with reference to FIG. 1. As in the case with FIG. 2, any of these capacitively coupled components may be coupled in the qubit plane, as shown, above the qubit plane, or below the qubit plane. The flux bias line 318 may be a flux bias line of the non-resonant transmission lines 108 and may also be in, above, or below the qubit plane as described above with reference to FIG. 2. Finally, FIG. 3 also illustrates ground planes 320, i.e. portions of electrically conductive, preferably superconductive, material connected to the ground or some other reference potential, surrounding the qubit 302. In some cases, certain regions of the ground plane capacitance could be positioned in, above, or below the qubit plane.

### Variations and Implementations

Quantum circuit assemblies shown in FIGS. 2 and 3 can vary significantly to achieve equivalent or similar results, and, therefore, should not be construed as the only possible implementations of quantum circuit assemblies in accordance with any one of the three proposed layout design concepts described herein. In particular, quantum circuit assemblies shown in FIGS. 2 and 3 should not be construed as the only possible implementations of quantum circuit assemblies where a capacitance between a coupling component and a portion of one of the two islands is greater than a capacitance between the islands, in accordance with the first layout design concept described herein. Further, quantum circuit assemblies shown in FIGS. 2 and 3 should not be construed as the only possible implementations of quantum circuit assemblies where one or more corners at one or more end portions of a coupling component and corresponding sections on the qubit are rounded, in accordance with the second layout design concept described herein. Still further, quantum circuit assemblies shown in FIGS. 2 and 3 should not be construed as the only possible implementations of quantum circuit assemblies where the distance between the islands is varied, in accordance with the third layout design concept described herein. Some of the possible variations and implementations of embodiments of the present disclosure compared to those shown in FIGS. 2 and 3 are described above alongside with the description of these FIGS., and some other possible variations and implementations are listed below. However, any of the variations and implementations which leverage one or more of the layout design concepts described herein are within the scope of the present disclosure.

While FIGS. 2 and 3 illustrate exemplary layout designs of quantum circuit assemblies where individual superconducting qubits have four nearest neighbors, in other embodiments any other number of nearest neighbor qubits may be implemented, e.g. qubit devices as shown in FIGS. 2 and 3, and various other embodiments of such devices described herein, may be coupled to any number of 3 or more nearest neighbor qubit devices using at least some of the coupling components as described herein.

While FIGS. 2 and 3 illustrate exemplary layout designs of quantum circuit assemblies implementing two Josephson Junctions in a SQUID, descriptions provided herein are equally applicable to quantum circuit assemblies where a superconducting qubit implements only one Josephson Junction and no SQUID, or to quantum circuit assemblies where the first and second islands are coupled to one another by one or more non-linear inductive elements.

While FIGS. 2 and 3 illustrate exemplary layout designs of quantum circuit assemblies where neither one of the first and second islands is connected to ground, i.e. the islands shown in FIGS. 2 and 3 are two ground-isolated islands, in other embodiments there could be only one ground-isolated island. Thus, in general, descriptions provided with respect to FIGS. 2 and 3 and various other embodiments of these FIGS. described herein are applicable to two scenarios. In a first scenario, neither one of the first and second islands is connected to ground, and there is a separate ground element (e.g. a ground plane such as e.g. ground planes 220, 320) providing ground isolation for the islands (i.e. the two islands described herein are two ground-isolated islands). In a second scenario, one of what is referred to here as the first or the second islands is connected to ground—e.g. the first and second islands 204/304 as shown in FIGS. 2 and 3 are electrically shorted together to form one ground-isolated island, the second “island” is the ground plane such as the ground planes 220, 320, and such new first and second islands are coupled to one another via one or more non-linear inductive elements (i.e. the single ground-isolated island would be connected to the surrounding ground plane which is the second island via one or more non-linear inductive elements, e.g. via the SQUID loop 206/306. In such a scenario, the total capacitance between the single ground-isolated island and the ground plane would be related to the charging energy and, therefore, the total capacitance budget as described above.

For each of FIGS. 2 and 3, both the microwave drive line 222/322 and readout resonator 214/314 do not need not be coupled capacitively in the same plane as the qubit islands, as shown in these FIGS., but could alternatively couple through an out-of-plane parallel-plate capacitive geometry, as described for the coupling bus resonators above.

Further, the flux bias line 218/318 does not need to be in the same plane as the qubit islands, as shown in FIGS. 2 and 3, but could be situated on a plane of different z-value (either above or below) the qubit plane.

### Fabrication Methods

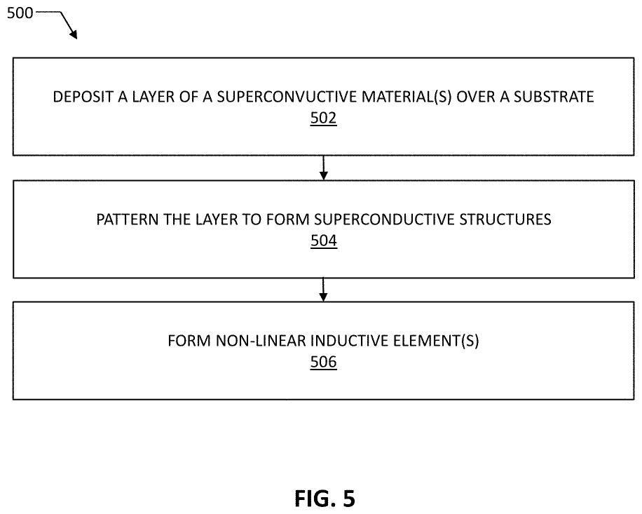

Various quantum circuit assemblies as discussed herein may be fabricated using any suitable fabrication methods. FIG. 5 provides a flow chart of one such method, a method 500 for fabricating quantum circuit assemblies with qubits arranged in accordance with layout designs described herein. Various operations of the method 500 may be illustrated with reference to some specific exemplary embodiments discussed above, but the method 500 may be used to manufacture any suitable quantum circuit assemblies with qubits arranged according to any of the designs described herein.

Although the operations of the method 500 are illustrated in FIG. 5 once each and in a particular order, the operations may be performed in any suitable order and repeated as desired. For example, one or more operations may be performed in parallel to manufacture multiple quantum circuit assemblies as described herein substantially simultaneously. In another example, the operations may be performed in a different order to reflect the architecture of a particular quantum circuit component in which one or more quantum circuit assemblies with superconducting qubits arranged in accordance with any of the layout designs described herein are to be included. In addition, the manufacturing method 500 may include other operations, not specifically shown in FIG. 5, such as e.g. various cleaning operations as known in the art. For example, in some embodiments, the substrate may be cleaned prior to or/and after any of the processes of the method 500 described herein, e.g. to remove surface-bound oxide, organic, and/or metallic contaminants, as well as subsurface contamination. In some embodiments, cleaning may be carried out using e.g. a chemical solutions (such as peroxide), and/or with ultraviolet (UV) radiation combined with ozone, and/or oxidizing the surface (e.g., using thermal oxidation) then removing the oxide (e.g. using hydrofluoric acid (HF)).

The method 500 may begin with a process 502 in which a layer of one or more electrically conductive, preferably superconductive materials is deposited over a substrate. Examples of deposition techniques for depositing such a layer include atomic layer deposition (ALD), physical vapor deposition (PVD) (e.g. evaporative deposition, magnetron sputtering, or e-beam deposition), chemical vapor deposition (CVD), or electroplating.

The method may then continue with processes 504 and 506, which may be performed in any order and not necessarily in the order shown in FIG. 5.

In the process 504, the layer deposited over the substrate in the process 502 is patterned to form superconductive structures such as e.g. a first element and a second element of a first qubit device, and a coupling component configured to capacitively couple to a portion of the first element so that a capacitance between the coupling component and the portion of the first element is greater than a capacitance between the first element and the second element. Examples of patterning techniques include photolithographic or electron-beam (e-beam) or optical patterning, possibly in conjunction with a dry etch, such as e.g. radio frequency (RF) reactive ion etch (RIE) or inductively coupled plasma (ICP) RIE, to pattern the layer of an electrically conductive material into structures of the specified geometries for a given implementation, e.g. to form the islands 204/304, the coupling components 210/310, and the ground planes 220/320 described herein.

In the process 506, one or more non-linear inductive elements of the first qubit device may be formed so that each of the first and the second elements are electrically connected to the one or more non-linear inductive elements. Various methods are known for providing non-linear inductive elements of quantum circuits, such as e.g. double-angle shadow evaporation method used to form Josephson Junctions, all of which being within the scope of the present disclosure.

Although not specifically shown in FIG. 5, the method 500 may further include removing one or more portions of the layer surrounding at least the first element until a capacitance between the first element and a ground element or the capacitance between the first and the second elements is smaller than the capacitance between the coupling component and the portion of the first element, where the ground element is a patterned portion of the layer that is directly electrically connected to a ground potential.

### Exemplary Qubit Devices

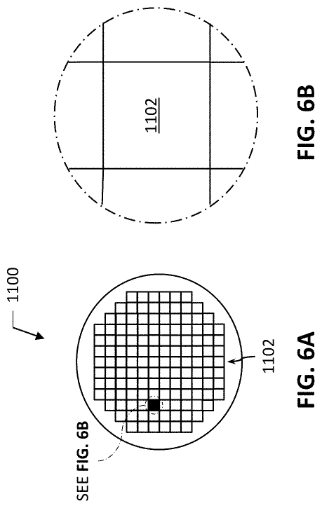

Quantum circuit assemblies/structures with superconducting qubits arranged in layout designs as described above may be included in any kind of qubit devices or quantum processing devices/structures. Some examples of such devices/structures are illustrated in FIGS. 6A-6B, 7, and 8.

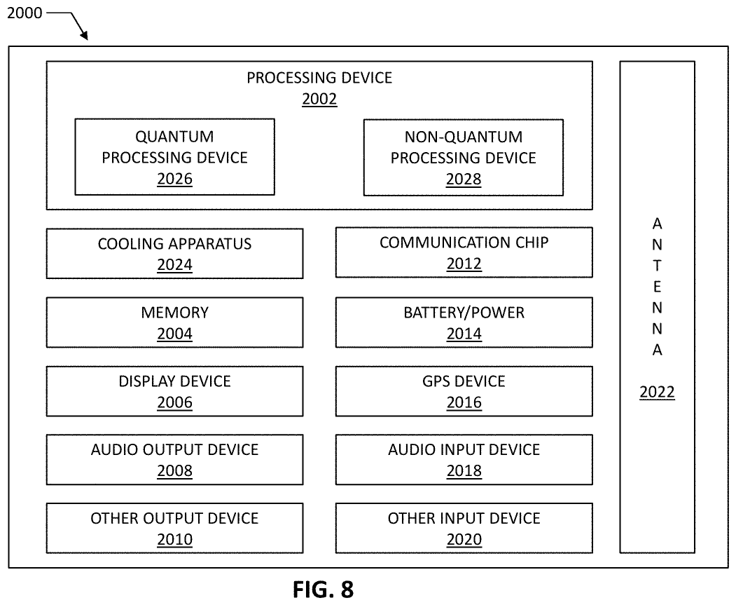

FIGS. 6A-6B are top views of a wafer 1100 and dies 1102 that may be formed from the wafer 1100, according to some embodiments of the present disclosure. The die 1102 may include any of the quantum circuit assemblies with qubit devices arranged in accordance with various layout designs described herein, e.g., the quantum circuit assemblies 200 or 300, any further embodiments of these assemblies as described herein (e.g. quantum circuit assemblies as shown in FIGS. 2-4 but with different numbers of nearest neighbor qubits, quantum circuit assemblies as shown in FIG. 2 but with the end portions of the coupling resonators having rounded corners, quantum circuit assemblies as shown in FIG. 2 but with varying distance between the islands, quantum circuit assemblies as shown in FIG. 3 but without the end portions of the coupling resonators having rounded corners, etc.), or any combinations of these assemblies. The wafer 1100 may include semiconductor material and may include one or more dies 1102 having conventional and quantum circuit device elements formed on a surface of the wafer 1100. Each of the dies 1102 may be a repeating unit of a semiconductor product that includes any suitable conventional and/or quantum circuit qubit device. After the fabrication of the semiconductor product is complete, the wafer 1100 may undergo a singulation process in which each of the dies 1102 is separated from one another to provide discrete “chips” of the semiconductor product. A die 1102 may include one or more quantum circuit assemblies with qubits arranged in accordance with any of the layout designs described herein, as well as other IC components. In some embodiments, the wafer 1100 or the die 1102 may include a memory device (e.g., a static random access memory (SRAM) device), a logic device (e.g., AND, OR, NAND, or NOR gate), or any other suitable circuit element. Multiple ones of these devices may be combined on a single die 1102. For example, a memory array formed by multiple memory devices may be formed on a same die 1102 as a processing device (e.g., the processing device 2002 of FIG. 8) or other logic that is configured to store information in the memory devices or execute instructions stored in the memory array.

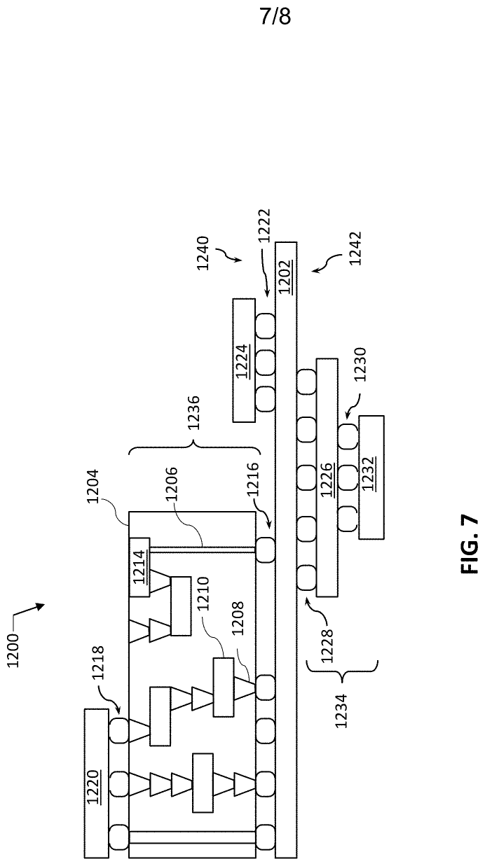

FIG. 7 is a cross-sectional side view of a device assembly 1200 that may include any of the quantum circuit assemblies with qubits arranged in accordance with various layout designs described herein. The device assembly 1200 includes a number of components disposed on a circuit board 1202. The device assembly 1200 may include components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1202. Signal transfer between components or layer may happen with both low resistance DC connections or by either in-plane or out-of-plane capacitive connections. In other embodiments, the circuit board 1202 may be a package substrate or flexible board.

The IC device assembly 1200 illustrated in FIG. 7 may include a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 7), male and female portions of a socket, an adhesive, an underfill material, and/or any other suitable electrical and/or mechanical coupling structure. The coupling components 1216 may include other forms of electrical connections that may have no mechanical contact, such as parallel-plate capacitors or inductors, which can allow high-frequency connection between components without mechanical or DC connection.

The package-on-interposer structure 1236 may include a package 1220 coupled to an interposer 1204 by coupling components 1218. The coupling components 1218 may take any suitable form for the application, such as the forms discussed above with reference to the coupling components 1216. Although a single package 1220 is shown in FIG. 7, multiple packages may be coupled to the interposer 1204; indeed, additional interposers may be coupled to the interposer 1204. The interposer 1204 may provide an intervening substrate used to bridge the circuit board 1202 and the package 1220. In some implementations, the package 1220 may be a quantum circuit device package as described herein, e.g. a package including one or more dies with any of the quantum circuit assemblies with qubit devices arranged in accordance with various layout designs described herein, e.g., the quantum circuit assemblies 200 or 300, any further embodiments of these assemblies as described herein (e.g. quantum circuit assemblies as shown in FIGS. 2-4 but with different numbers of nearest neighbor qubits, quantum circuit assemblies as shown in FIG. 2 but with the end portions of the coupling resonators having rounded corners, quantum circuit assemblies as shown in FIG. 2 but with varying distance between the islands, quantum circuit assemblies as shown in FIG. 3 but without the end portions of the coupling resonators having rounded corners, etc.), or any combinations of these assemblies. In other implementations, the package 1220 may be a conventional IC package with non-quantum circuit assemblies. Generally, the interposer 1204 may spread a connection to a wider pitch or reroute a connection to a different connection. For example, the interposer 1204 may couple the package 1220 (e.g., a die) to a ball grid array (BGA) of the coupling components 1216 for coupling to the circuit board 1202. In the embodiment illustrated in FIG. 7, the package 1220 and the circuit board 1202 are attached to opposing sides of the interposer 1204; in other embodiments, the package 1220 and the circuit board 1202 may be attached to a same side of the interposer 1204. In some embodiments, three or more components may be interconnected by way of the interposer 1204.

The interposer 1204 may be formed of a crystalline material, such as silicon, germanium, or other semiconductors, an epoxy resin, a fiberglass-reinforced epoxy resin, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1210 and vias 1208, including but not limited to through-silicon vias (TSVs) 1206. The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The device assembly 1200 may include a package 1224 coupled to the first face 1240 of the circuit board 1202 by coupling components 1222. The coupling components 1222 may take the form of any of the embodiments discussed above with reference to the coupling components 1216, and the package 1224 may take the form of any of the embodiments discussed above with reference to the package 1220. Thus, the package 1224 may be a package including one or more quantum circuits with qubits arranged in accordance with any of the layout designs described herein or may be a conventional IC package, for example. In some embodiments, the package 1224 may take the form of any of the embodiments of the quantum circuit assemblies with qubits arranged in accordance with various layout designs described herein, e.g., the quantum circuit assemblies 200 or 300, any further embodiments of these assemblies as described herein, or any combinations of these assemblies.

The device assembly 1200 illustrated in FIG. 7 includes a package-on-package structure 1234 coupled to the second face 1242 of the circuit board 1202 by coupling components 1228. The package-on-package structure 1234 may include a package 1226 and a package 1232 coupled together by coupling components 1230 such that the package 1226 is disposed between the circuit board 1202 and the package 1232. The coupling components 1228 and 1230 may take the form of any of the embodiments of the coupling components 1216 discussed above, and the packages 1226 and 1232 may take the form of any of the embodiments of the package 1220 discussed above. Each of the packages 1226 and 1232 may be a qubit device package as described herein or may be a conventional IC package, for example. In some embodiments, one or both of the packages 1226 and 1232 may take the form of any of the embodiments of the quantum circuit assemblies with qubit devices arranged in accordance with various layout designs described herein, e.g., the quantum circuit assemblies 200 or 300, any further embodiments of these assemblies as described herein, or any combinations of these assemblies.

FIG. 8 is a block diagram of an exemplary quantum computing device 2000 that may include one or more of quantum circuit assemblies with qubits arranged in accordance with any of the layout designs described herein, according to some embodiments of the present disclosure. A number of components are illustrated in FIG. 8 as included in the quantum computing device 2000, but any one or more of these components may be omitted or duplicated, as suitable for the application. In some embodiments, some or all of the components included in the quantum computing device 2000 may be attached to one or more PCBs (e.g., a motherboard), and may be included in, or include, any of the quantum circuits with any of the quantum circuit assemblies described herein. In some embodiments, various ones of these components may be fabricated onto a single system-on-a-chip (SoC) die. Additionally, in various embodiments, the quantum computing device 2000 may not include one or more of the components illustrated in FIG. 8, but the quantum computing device 2000 may include interface circuitry for coupling to the one or more components. For example, the quantum computing device 2000 may not include a display device 2006, but may include display device interface circuitry (e.g., a connector and driver circuitry) to which a display device 2006 may be coupled. In another set of examples, the quantum computing device 2000 may not include an audio input device 2018 or an audio output device 2008, but may include audio input or output device interface circuitry (e.g., connectors and supporting circuitry) to which an audio input device 2018 or audio output device 2008 may be coupled. In further examples, the quantum computing device 2000 may include a microwave input device or a microwave output device (not specifically shown in FIG. 8), or may include microwave input or output device interface circuitry (e.g., connectors and supporting circuitry) to which a microwave input device or microwave output device may be coupled.

The quantum computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may include a quantum processing device 2026 (e.g., one or more quantum processing devices), and a non-quantum processing device 2028 (e.g., one or more non-quantum processing devices). The quantum processing device 2026 may include one or more of the quantum circuit assemblies with qubits arranged in accordance with various layout designs described herein, e.g., the quantum circuit assemblies 200 or 300, any further embodiments of these assemblies as described herein, or any combinations of these assemblies, and may perform data processing by performing operations on the qubits that may be generated in these quantum circuit assemblies, and monitoring the result of those operations. For example, as discussed above, different qubits may be allowed to interact, the quantum states of different qubits may be set or transformed, and the quantum states of different qubits may be read. The quantum processing device 2026 may be a universal quantum processor, or specialized quantum processor configured to run one or more particular quantum algorithms. In some embodiments, the quantum processing device 2026 may execute algorithms that are particularly suitable for quantum computers, such as cryptographic algorithms that utilize prime factorization, encryption/decryption, algorithms to optimize chemical reactions, algorithms to model protein folding, etc. The quantum processing device 2026 may also include support circuitry to support the processing capability of the quantum processing device 2026, such as input/output channels, multiplexers, signal mixers, quantum amplifiers, and analog-to-digital converters.

As noted above, the processing device 2002 may include a non-quantum processing device 2028. In some embodiments, the non-quantum processing device 2028 may provide peripheral logic to support the operation of the quantum processing device 2026. For example, the non-quantum processing device 2028 may control the performance of a read operation, control the performance of a write operation, control the clearing of quantum bits, etc. The non-quantum processing device 2028 may also perform conventional computing functions to supplement the computing functions provided by the quantum processing device 2026. For example, the non-quantum processing device 2028 may interface with one or more of the other components of the quantum computing device 2000 (e.g., the communication chip 2012 discussed below, the display device 2006 discussed below, etc.) in a conventional manner, and may serve as an interface between the quantum processing device 2026 and conventional components. The non-quantum processing device 2028 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

The quantum computing device 2000 may include a memory 2004, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, the states of qubits in the quantum processing device 2026 may be read and stored in the memory 2004. In some embodiments, the memory 2004 may include memory that shares a die with the non-quantum processing device 2028. This memory may be used as cache memory and may include embedded dynamic random access memory (eDRAM) or spin transfer torque magnetic random access memory (STT-MRAM).

The quantum computing device 2000 may include a cooling apparatus 2024. The cooling apparatus 2024 may maintain the quantum processing device 2026, in particular the quantum circuits 100 as described herein, at a predetermined low temperature during operation to avoid qubit decoherence and to reduce the effects of scattering in the quantum processing device 2026. This predetermined low temperature may vary depending on the setting; in some embodiments, the temperature may be 5 degrees Kelvin or less. In some embodiments, the non-quantum processing device 2028 (and various other components of the quantum computing device 2000) may not be cooled by the cooling apparatus 2030, and may instead operate at room temperature. The cooling apparatus 2024 may be, for example, a dilution refrigerator, a helium-3 refrigerator, or a liquid helium refrigerator.

In some embodiments, the quantum computing device 2000 may include a communication chip 2012 (e.g., one or more communication chips). For example, the communication chip 2012 may be configured for managing wireless communications for the transfer of data to and from the quantum computing device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The quantum computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some embodiments, a first communication chip 2012 may be dedicated to wireless communications, and a second communication chip 2012 may be dedicated to wired communications.

The quantum computing device 2000 may include battery/power circuitry 2014. The battery/power circuitry 2014 may include one or more energy storage devices (e.g., batteries or capacitors) and/or circuitry for coupling components of the quantum computing device 2000 to an energy source separate from the quantum computing device 2000 (e.g., AC line power).

The quantum computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display, for example.

The quantum computing device 2000 may include an audio output device 2008 (or corresponding interface circuitry, as discussed above). The audio output device 2008 may include any device that generates an audible indicator, such as speakers, headsets, or earbuds, for example.

The quantum computing device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The quantum computing device 2000 may include a GPS device 2016 (or corresponding interface circuitry, as discussed above). The GPS device 2016 may be in communication with a satellite-based system and may receive a location of the quantum computing device 2000, as known in the art.

The quantum computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The quantum computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The quantum computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

### SELECT EXAMPLES

The following paragraphs provide examples of various ones of the embodiments disclosed herein.

Example 1 provides a quantum circuit assembly that includes a first qubit device and a coupling component. The first qubit device includes a first element and a second element (referred to in the present disclosure as “islands,” where one of the elements may, but does not have to be directly part of the ground plane), the first and second elements including (e.g. made of) one or more superconductive materials and electrically connected to at least one non-linear inductive element (i.e. the first and second elements are connected to one another via one or more non-linear inductive elements such as e.g. Josephson Junctions). The coupling component can be e.g. a coupling component on a neighboring qubit device (e.g. on a second qubit device mentioned below), a lumped element capacitor, a lumped element resonator, or a transmission line segment. The coupling component is configured to, during operation of the quantum circuit assembly, capacitively couple itself to a portion of the first element and thereby couple the first qubit device and a second qubit device, where a capacitance between the coupling component and the portion of the first element is greater than a capacitance between the first element and the second element.

Example 2 provides the quantum circuit assembly according to Example 1, where the first qubit device is coupled to three or more other qubit devices via respective ones of three or more coupling components.

Example 3 provides the quantum circuit assembly according to Example 1, where the coupling component is a first coupling component, the portion of the first element is a first portion of the first element, and the quantum circuit assembly further includes a second coupling component configured to, during operation of the quantum circuit assembly, capacitively couple to a portion of the second element or a second portion of the first element to couple the first qubit device and a third qubit device, where a capacitance between the second coupling component and either the portion of the second element or the second portion of the first element is greater than the capacitance between the first element and the second element.

Example 4 provides the quantum circuit assembly according to Example 3, where the quantum circuit assembly further includes a third coupling components configured to, during operation of the quantum circuit assembly, capacitively couple the first qubit device and a fourth qubit device.

Example 5 provides the quantum circuit assembly according to Example 1, where the second qubit device is one of a plurality of qubit devices configured to be coupled to the first qubit device, where the coupling component is one of a plurality of coupling components, and where individual coupling components of the plurality of coupling components are configured to, during operation of the quantum circuit assembly, capacitively couple to individual portions of one of the first and the second elements to couple the first qubit device and individual qubit devices of the plurality of qubit devices, where capacitances between any of the individual coupling components and the individual portions of one of the first and the second elements are greater than the capacitance between the first element and the second element. In other words, there is one-to-one correspondence between a plurality of coupling resonators and a plurality of qubit devices coupled to the first qubit device, where each coupling resonator of the plurality of coupling resonators couples a different qubit device of the plurality of qubit devices to the first qubit device, by capacitively coupling to a different portion of the first or second element of the first qubit device.

Example 6 provides the quantum circuit assembly according to Example 5, where the plurality of qubit devices includes at least four qubit devices and the plurality of coupling components includes at least three coupling components.

Example 7 provides the quantum circuit assembly according to Example 6, where at least three coupling components includes at least four coupling components and where, during operation of the quantum circuit assembly, two of the at least four coupling components are configured to capacitively couple to two different portions of the first element and another two of the at least four coupling components are configured to capacitively couple to two different portions of the second element.

Example 8 provides the quantum circuit assembly according to any one of Examples 1-7, where a shape of a portion of the coupling component that is coupled to the portion of the first element is meandering (i.e. following a winding course, or including a plurality of convex and concave portions) and conformal to a shape of the portion of the first element, the two said portions separated by a thin gap as to form a capacitor of an interlocking puzzle-piece shape, e.g. an interdigitated capacitor with one or more rounded corners.

Example 9 provides the quantum circuit assembly according to any one of Examples 1-7, where the portion of the first element and a portion of the coupling component that is coupled to the portion of the first element form an interdigitated capacitor.

Example 10 provides the quantum circuit assembly according to any one of Examples 1-7, where a portion of the coupling component that is coupled to the portion of the first element is provided in a plane different from, and parallel to, a plane of the portion of the first element and is separated from the plane of the portion of the first element by a gap. In various embodiments, such portions may have any suitable, including irregular, e.g. meandering, shapes/geometries, as long as parts of them overlap to form a parallel-plate capacitor (“parallel-plate” because portions lie in parallel planes separated by a gap).

Example 11 provides the quantum circuit assembly according to any one of Examples 1-10, where the capacitance between the coupling component and the portion of the first element is greater than a capacitance between the first element and a ground element, where the ground element includes one or more superconductive materials directly electrically connected to a DC ground potential. In this Example, the ground element is a superconductive element different from the first and the second elements.

Example 12 provides the quantum circuit assembly according to Example 11, where the capacitance between the coupling component and the portion of the first element is greater than a capacitance between the second element and the ground element.

Example 13 provides the quantum circuit assembly according to any one of Examples 1-10, where the second element is directly electrically connected to a direct-current (DC) ground potential and where the capacitance between the coupling component and the portion of the first element is greater than a capacitance between the first element and the second element.

Example 14 provides the quantum circuit assembly according to any one of the preceding Examples, where the capacitance between the coupling component and the portion of the first element is greater than the capacitance between the first element and the second element by at least a factor of about 2, e.g. at least a factor of about 3 or at least a factor of about 5.

Example 15 provides the quantum circuit assembly according to any one of the preceding Examples, where a distance between the first element and the second element (namely, the distance between the portions of the first and second elements which are opposite one another) varies by a factor of at least about 1.5, including all values and ranges therein, e.g. by a factor between about 1.5 and 10, or by a factor between about 2 and 5.

Example 16 provides the quantum circuit assembly according to any one of the preceding Examples, where at least one corner of a portion of the coupling component that is configured to capacitively couple to the portion of the first element is rounded, and/or the corresponding corner on the first element is correspondingly rounded.

Example 17 provides the quantum circuit assembly according to Example 16, where at least 80 percent of all corners of the portion of the coupling component that is configured to capacitively couple to the portion of the first element are rounded, and/or the corresponding corners on the first element are correspondingly rounded.

Example 18 provides the quantum circuit assembly according to any one of the preceding Examples, where the at least one non-linear inductive element is part of a SQUID that includes two or more non-linear inductive elements.

Example 19 provides the quantum circuit assembly according to any one of the preceding Examples, further including a flux bias line, provided either in or out of the qubit plane, configured to control a frequency of the first qubit device by providing electromagnetic fields which couple to the non-linear inductive elements of the first qubit device.

Example 20 provides the quantum circuit assembly according to any one of the preceding Examples, further including a readout resonator, provided either in or out of the qubit plane, configured to detect (readout) a state of the first qubit device by capacitively coupling, during operation of the quantum circuit assembly, to a portion of the first or the second element.

Example 21 provides the quantum circuit assembly according to any one of the preceding Examples, further including a direct drive line, provided either in or out of the qubit plane, configured to set a state of the first qubit device by capacitively coupling, during operation of the quantum circuit assembly, to a portion of the first or the second element.

Example 22 provides a method of fabricating a quantum circuit assembly. The method includes depositing a layer including one or more electrically conductive, preferably superconductive materials over a substrate; patterning the layer to form a first element and a second element of a first qubit device, and to form a coupling component configured to capacitively couple to a portion of the first element so that a capacitance between the coupling component and the portion of the first element is greater than a capacitance between the first element and the second element; and forming one or more non-linear inductive elements of the first qubit device so that each of the first and the second elements are electrically connected to the one or more non-linear inductive elements.

Example 23 provides the method according to Example 22, further including removing one or more portions of the layer surrounding at least the first element until a capacitance between the first element and a ground element or the capacitance between the first and the second elements is smaller than the capacitance between the coupling component and the portion of the first element, where the ground element is a patterned portion of the layer that is directly electrically connected to a ground potential.

Example 24 provides a quantum circuit assembly that includes a substrate, a first qubit device, and a coupling component provided over, on, or at least partially in the substrate and including a first end portion forming a first electrode of a first capacitor for coupling the coupling component to a first qubit device, where a portion of the first qubit device opposite the first end portion forms a second electrode of the first capacitor, and a second end portion forming a first electrode of a second capacitor for coupling the coupling component to a second qubit device, where a portion of the second qubit device opposite the second end portion forms a second electrode of the second capacitor. In such an Example, one or more corners of the first end portion or of the second end portion, preferably at least 80% or substantially all corners of both the first and second end portions of the coupling resonator are rounded.

Example 25 provides the quantum circuit assembly according to Example 24, where for at least one of the first and second capacitors, a shape of the first electrode is conformal to a shape of the second electrode and may either be in an interdigitated or similar geometry, or a parallel-plate geometry (i.e. the shortest distance between each point of the first electrode and the closest point of the second electrode remains the same for all points of the first and second electrodes). When the first electrodes of the first and second capacitors (i.e. the first and second end portions of the coupling resonator) have rounded corners, the second electrodes of these capacitors (i.e. the corresponding portions of the first and second qubit devices) have rounded corners as well.

Example 26 provides the quantum circuit assembly according to Examples 24 or 25, where the portion of the first qubit device opposite the first end portion of the coupling resonator is a portion of a first element of the first qubit device, the first qubit device further including a second element, where each of the first and second elements are connected to one or more non-linear inductive elements, and where a capacitance between the first end portion of the coupling component and the portion of the first qubit device opposite the first end portion of the coupling component is greater than a capacitance between the first element and the second element of the first qubit device and, in some embodiments, greater than a capacitance between one or both of the first and second elements of the first qubit device and the ground. The same may apply to the second qubit device.

Example 27 provides the quantum circuit assembly according to any one of Examples 24-26, where the at least one of the first capacitor and the second capacitor is an interdigitated capacitor where at least some fingers of the electrode of the interdigitated capacitor that is formed by a respective end of the coupling resonator are rounded.

In various further Examples, quantum circuit assemblies according to any one of Examples 24-27 may further include features of any of the quantum circuit assemblies according to any one of Examples 1-21.

Example 28 provides a quantum circuit assembly that includes a first qubit device including a first element and a second element opposite the first element (the first and second elements referred to in the present disclosure as “islands”). The first and second elements include (e.g. made of) one or more superconductive materials and electrically connected to at least one non-linear inductive element (i.e. the first and second elements are connected to one another via one or more non-linear inductive elements such as Josephson Junctions), a distance between the first element and the second element (namely, the distance between the portions of the first and second elements which are opposite one another) varies by a factor of at least about 1.5, including all values and ranges therein, e.g. by a factor between about 1.5 and 10, or by a factor between about 1.5 and 5, and none of the first and second elements is connected to a ground potential or/and the first qubit device is coupled to three or more other qubit devices via respective ones of three or more coupling components.

Example 29 provides the quantum circuit assembly according to Example 28, further including a coupling resonator configured to, during operation of the quantum circuit assembly, capacitively couple to a portion of the first element to couple the first qubit device and a second qubit device, where a capacitance between the coupling resonator and the portion of the first element is greater than a capacitance between the first element and the second element.

Example 30 provides the quantum circuit assembly according to Example 29, where at least one corner of a portion of the coupling resonator that is configured to capacitively couple to the portion of the first element is rounded.

In various further Examples, quantum circuit assemblies according to any one of Examples 28-30 may further include features of any of the quantum circuit assemblies according to any one of Examples 1-21 or/and may further include features of any of the quantum circuit assemblies according to any one of Examples 24-27.

Example 31 provides a quantum IC package that includes a substrate; a first qubit device and a second qubit device provided over, on, or at least partially in the substrate; and a coupling component provided over, on, or at least partially in the substrate and including a first portion and a second portion. The first portion of the coupling component is configured to (during operation of the qubit devices) capacitively couple to a portion of the first qubit device, the second portion is configured to (during operation of the qubit devices) capacitively couple to a portion of the second qubit device, and a capacitance between the first portion of the coupling component and the portion of the first qubit device is greater than a capacitance between the portion of the first qubit device and a further portion of the first qubit device, where the portion and the further portion of the first qubit device are coupled to one another via one or more non-linear inductive elements.

Example 32 provides the quantum IC package according to Example 31, where the substrate, the first and the second qubit devices and the coupling components are part of a qubit die, and where the quantum IC package further includes a further IC element, where the qubit die is coupled to the further IC element by one or more interconnects between the further IC element and the qubit die.

Example 33 provides the quantum IC package according to Example 32, where the further IC element is one of an interposer, a circuit board, a flexible board, or a package substrate.

In various further Examples, quantum IC package according to any one of Examples 31-33 may further include features of any of the quantum circuit assemblies according to any one of Examples 1-21 or/and may further include features of any of the quantum circuit assemblies according to any one of Examples 24-27 or/and may further include features of any of the quantum circuit assemblies according to any one of Examples 28-30.

Example 34 provides a quantum IC package that includes a substrate; a first qubit device and a second qubit device provided over, on, or at least partially in the substrate; and a coupling component provided over, on, or at least partially in the substrate. The coupling component includes a first portion forming a first electrode of a first capacitor for coupling the coupling component to the first qubit device, where a portion of the first qubit device opposite the first portion forms a second electrode of the first capacitor, and a second portion forming a first electrode of a second capacitor for coupling the coupling component to a second qubit device, where a portion of the second qubit device opposite the second portion forms a second electrode of the second capacitor, where one or more corners of the first portion or of the second portion, preferably at least 80% or substantially all corners of both the first and second end portions of the coupling resonator, are rounded.

Example 35 provides the quantum IC package according to Example 34, where the substrate, the first and the second qubit devices and the coupling components are part of a qubit die, and where the quantum IC package further includes a further IC element, where the qubit die is coupled to the further IC element by one or more interconnects between the further IC element and the qubit die.

Example 36 provides the quantum IC package according to Example 35, where the further IC element is one of an interposer, a circuit board, a flexible board, or a package substrate.

In various further Examples, quantum IC package according to any one of Examples 34-36 may further include features of any of the quantum circuit assemblies according to any one of Examples 1-21 or/and may further include features of any of the quantum circuit assemblies according to any one of Examples 24-27 or/and may further include features of any of the quantum circuit assemblies according to any one of Examples 28-30.

Example 37 provides a quantum IC package that includes a substrate; and a first qubit device provided over, on, or at least partially in the substrate. The first qubit device includes a first element and a second element opposite the first element, the first and second elements include (e.g. made of) one or more superconductive materials and electrically connected to at least one non-linear inductive element (i.e. the first and second elements are connected to one another via one or more non-linear inductive elements such as Josephson Junctions), and a distance between the first element and the second element (namely, the distance between the portions of the first and second elements which are opposite one another) varies by a factor of at least about 1.5, including all values and ranges therein, e.g. by a factor between about 1.5 and 10, or by a factor between about 1.5 and 5. Furthermore, none of the first and second elements is connected to a ground potential or/and the first qubit device is coupled to three or more other qubit devices via respective ones of three or more coupling components.

Example 38 provides the quantum IC package according to Example 37, where the substrate, the first and the second qubit devices and the coupling components are part of a qubit die, and where the quantum IC package further includes a further IC element, where the qubit die is coupled to the further IC element by one or more interconnects between the further IC element and the qubit die.

Example 39 provides the quantum IC package according to Example 38, where the further IC element is one of an interposer, a circuit board, a flexible board, or a package substrate.

In various further Examples, quantum IC package according to any one of Examples 37-39 may further include features of any of the quantum circuit assemblies according to any one of Examples 1-21 or/and may further include features of any of the quantum circuit assemblies according to any one of Examples 24-27 or/and may further include features of any of the quantum circuit assemblies according to any one of Examples 28-30.

Example 40 provides a quantum computing device that includes a quantum processing device that includes a die including a substrate, a coupling component, and a plurality of qubits over, on or at least partially in the substrate; and a memory device configured to store data generated by the plurality of qubits during operation of the quantum processing device. The plurality of qubits includes at least a first qubit and a second qubit, the first qubit including a first portion and a second portion coupled to one another via one or more non-linear inductive elements, the coupling component includes a first portion configured to (during operation of the quantum processing device) capacitively couple to the first portion of the first qubit, and a second portion configured to (during operation of the quantum processing device) capacitively couple to a portion of the second qubit, and a capacitance between the first portion of the coupling component and the first portion of the first qubit is greater than a capacitance between the first portion of the first qubit and the second portion of the first qubit.

Example 41 provides the quantum computing device according to Example 40, further including a cooling apparatus configured to maintain a temperature of the quantum processing device below 5 degrees Kelvin.

Example 42 provides the quantum computing device according to Examples 40 or 41, where the memory device is configured to store instructions for a quantum computing algorithm to be executed by the quantum processing device.

Example 43 provides the quantum computing device according to any one of Examples 40-42, further including a non-quantum processing device coupled to the quantum processing device.

In various further Examples, the quantum processing device according to any one of Examples 40-43 may further include features of any of the quantum circuit assemblies according to any one of Examples 1-21 and 24-30, or/and may further include features of any of the quantum IC packages according to any one of the preceding Examples.

Example 44 provides a quantum computing device that includes a quantum processing device that includes a die including a substrate, a coupling component, and a plurality of qubits over, on or at least partially in the substrate; and a memory device configured to store data generated by the plurality of qubits during operation of the quantum processing device. The plurality of qubits includes at least a first qubit and a second qubit, the coupling component includes a first portion forming a first electrode of a first capacitor for coupling the coupling component to the first qubit, where a portion of the first qubit opposite the first portion forms a second electrode of the first capacitor, the coupling component includes a second portion forming a first electrode of a second capacitor for coupling the coupling component to the second qubit, where a portion of the second qubit opposite the second portion forms a second electrode of the second capacitor, and one or more corners of the first portion or of the second portion, preferably at least 80% or substantially all corners of both the first and second end portions of the coupling resonator, are rounded.

Example 45 provides the quantum computing device according to Example 44, further including a cooling apparatus configured to maintain a temperature of the quantum processing device below 5 degrees Kelvin.

Example 46 provides the quantum computing device according to Examples 44 or 45, where the memory device is configured to store instructions for a quantum computing algorithm to be executed by the quantum processing device.

Example 47 provides the quantum computing device according to any one of Examples 44-46, further including a non-quantum processing device coupled to the quantum processing device.

In various further Examples, the quantum processing device according to any one of Examples 44-47 may further include features of any of the quantum circuit assemblies according to any one of Examples 1-21 and 24-30, or/and may further include features of any of the quantum IC packages according to any one of the preceding Examples.

Example 48 provides a quantum computing device that includes a quantum processing device that includes a die including a substrate, a coupling component, and a plurality of qubits over, on or at least partially in the substrate; and a memory device configured to store data generated by the plurality of qubits during operation of the quantum processing device. The plurality of qubits includes at least a first qubit including a first element and a second element opposite the first element, the first and second elements include (e.g. made of) one or more superconductive materials and electrically connected to at least one non-linear inductive element (i.e. the first and second elements are connected to one another via one or more non-linear inductive elements such as Josephson Junctions), a distance between the first element and the second element (namely, the distance between the portions of the first and second elements which are opposite one another) varies by a factor of at least about 1.5, including all values and ranges therein, e.g. by a factor between about 1.5 and 10, or by a factor between about 1.5 and 5, and none of the first and second elements is connected to a ground potential or/and the first qubit device is coupled to three or more other qubit devices via respective ones of three or more coupling components.

Example 49 provides the quantum computing device according to Example 48, further including a cooling apparatus configured to maintain a temperature of the quantum processing device below 5 degrees Kelvin.

Example 50 provides the quantum computing device according to Examples 48 or 49, where the memory device is configured to store instructions for a quantum computing algorithm to be executed by the quantum processing device.

Example 51 provides the quantum computing device according to any one of Examples 48-50, further including a non-quantum processing device coupled to the quantum processing device.

In various further Examples, the quantum processing device according to any one of Examples 48-51 may further include features of any of the quantum circuit assemblies according to any one of Examples 1-21 and 24-30, or/and may further include features of any of the quantum IC packages according to any one of the preceding Examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A quantum circuit assembly comprising:
a first qubit device that includes a first element and a second element, the first and second elements including one or more superconductive materials and connected to at least one non-linear inductive element; and
a coupling component configured to capacitively couple to a portion of the first element and thereby couple the first qubit device and a second qubit device,
wherein a capacitance between the coupling component and the portion of the first element is greater than a capacitance between the first element and the second element.

2. The quantum circuit assembly according to claim 1, wherein the first qubit device is coupled to three or more other qubit devices.

3. The quantum circuit assembly according to claim 1, wherein the coupling component is a first coupling component, the portion of the first element is a first portion of the first element, and the quantum circuit assembly further comprises a second coupling component configured to capacitively couple to a portion of the second element or a second portion of the first element to couple the first qubit device and a third qubit device, wherein a capacitance between the second coupling component and either the portion of the second element or the second portion of the first element is greater than the capacitance between the first element and the second element.

4. The quantum circuit assembly according to claim 3, wherein the quantum circuit assembly further comprises a third coupling components configured to capacitively couple the first qubit device and a fourth qubit device.

5. The quantum circuit assembly according to claim 1, wherein the second qubit device is one of a plurality of qubit devices configured to be coupled to the first qubit device, wherein the coupling component is one of a plurality of coupling components, and wherein individual coupling components are configured to capacitively couple to individual portions of one of the first and the second elements to couple the first qubit device and individual qubit devices of the plurality of qubit devices, where capacitances between any of the individual coupling components and the individual portions of one of the first and the second elements are greater than the capacitance between the first element and the second element.

6. The quantum circuit assembly according to claim 5, wherein the plurality of qubit devices comprises at least four qubit devices and the plurality of coupling components comprises at least three coupling components.

7. The quantum circuit assembly according to claim 6, wherein at least three coupling components comprises at least four coupling components and wherein two of the at least four coupling components are configured to capacitively couple to two different portions of the first element and another two of the at least four coupling components are configured to capacitively couple to two different portions of the second element.

8. The quantum circuit assembly according to claim 1, wherein a shape of a portion of the coupling component that is coupled to the portion of the first element is meandering and conformal to a shape of the portion of the first element.

9. The quantum circuit assembly according to claim 1, wherein the portion of the first element and a portion of the coupling component that is coupled to the portion of the first element form an interdigitated capacitor.

10. The quantum circuit assembly according to claim 1, wherein a portion of the coupling component that is coupled to the portion of the first element is provided in a plane different from a plane of the portion of the first element and is separated from the portion of the first element by a gap.

11. The quantum circuit assembly according to claim 1, wherein:
the capacitance between the coupling component and the portion of the first element is greater than a capacitance between the first element and a ground element,
the ground element comprises one or more superconductive materials connected to a direct-current (DC) ground potential, and
the capacitance between the coupling component and the portion of the first element is greater than a capacitance between the second element and the ground element.

12. (canceled)

13. The quantum circuit assembly according to claim 1, wherein the second element is connected to a direct-current (DC) ground potential and wherein the capacitance between the coupling component and the portion of the first element is greater than a capacitance between the first element and the second element.

14. The quantum circuit assembly according to claim 1, wherein the capacitance between the coupling component and the portion of the first element is greater than the capacitance between the first element and the second element by at least a factor of about 3.

15. The quantum circuit assembly according to claim 1, wherein a distance between the first element and the second element varies by a factor of at least 1.5.

16. The quantum circuit assembly according to claim 1, wherein at least one corner of a portion of the coupling component that is configured to capacitively couple to the portion of the first element is rounded.

17. The quantum circuit assembly according to claim 16, wherein at least 80 percent of all corners of the portion of the coupling component that is configured to capacitively couple to the portion of the first element are rounded.

18-21. (canceled)

22. A method of fabricating a quantum circuit assembly, the method comprising:
depositing a layer comprising one or more superconductive materials over a substrate;
patterning the layer to form a first element and a second element of a first qubit device, and to form a coupling component configured to capacitively couple to a portion of the first element so that a capacitance between the coupling component and the portion of the first element is greater than a capacitance between the first element and the second element; and
forming one or more non-linear inductive elements of the first qubit device so that each of the first and the second elements are connected to the one or more non-linear inductive elements.

23. The method according to claim 22, further comprising removing one or more portions of the layer surrounding at least the first element so that a capacitance between the first element and a ground element or the capacitance between the first and the second elements is smaller than the capacitance between the coupling component and the portion of the first element, where the ground element is a patterned portion of the layer that is connected to a ground potential.

24. A quantum circuit assembly comprising:
a substrate;
a coupling component provided over, on, or at least partially in the substrate and comprising:
a first end portion forming a first electrode of a first capacitor for coupling the coupling component to a first qubit device, where a portion of the first qubit device opposite the first end portion forms a second electrode of the first capacitor, and
a second end portion forming a first electrode of a second capacitor for coupling the coupling component to a second qubit device, where a portion of the second qubit device opposite the second end portion forms a second electrode of the second capacitor,
wherein:
one or more corners of the first end portion or of the second end portion are rounded.

25. The quantum circuit assembly according to claim 24, where for at least one of the first and second capacitors, a shape of the first electrode is conformal to a shape of the second electrode.
